(19) United States
(12) Patent Application Publication
(10) Pub. No.: US 2024/0244906 A1
(43) Pub. Date: Jul. 18, 2024

(54) DISPLAY DEVICE

(71) Applicant: Samsung Display Co., LTD., Yongin-si (KR)

(72) Inventors: Sun Kwun SON, Yongin-si (KR); Dong Hee SHIN, Yongin-si (KR); Hyung Jin SONG, Yongin-si (KR)

(73) Assignee: Samsung Display Co., LTD., Yongin-si (KR)

(21) Appl. No.: 18/465,261

(22) Filed: Sep. 12, 2023

(30) Foreign Application Priority Data
Jan. 13, 2023 (KR) 10-2023-0005572

(51) Int. Cl. H10K 59/131; H10K 59/121

(52) U.S. Cl. CPC H10K 59/131; H10K 59/1216

(57) ABSTRACT

A transistor may include: first, second, and third sub-pixels adjacent to each other, each of the first, second, and third sub-pixels including a storage capacitor; a scan line selectively transferring a scan signal and a control signal to each of the first, second, and third sub-pixels, the scan line extending in a first direction; a data line transferring a data signal to each of the first, second, and third sub-pixels, the data line extending in a second direction intersecting the first direction; and a first power line electrically connected to each of the first, second, and third sub-pixels, and the first power line being supplied with a first driving power voltage. The first power line may be disposed between the storage capacitor and the data line.

### CROSS-REFERENCE TO RELATED APPLICATION(S)

The application claims priority to and benefits of Korean patent application No. 10-2023-0005572 under 35 U.S.C. § 119, filed on Jan. 13, 2023, in the Korean Intellectual Property Office, the entire contents of which are incorporated herein by reference.

### BACKGROUND

### 1. Technical Field

Embodiments relate to a display device.

### 2. Description of the Related Art

Recently, as interest in information displays increases, research and development of display devices have been continuously conducted.

### SUMMARY

Embodiments provide a display device capable of improving reliability.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: first, second, and third sub-pixels adjacent to each other, each of the first, second, and third sub-pixels including a storage capacitor; a scan line selectively transferring a scan signal and a control signal to each of the first, second, and third sub-pixels, the scan line extending in a first direction; a data line transferring a data signal to each of the first, second, and third sub-pixels, the data line extending in a second direction intersecting the first direction; and a first power line electrically connected to each of the first, second, and third sub-pixels, and the first power line being supplied with a first driving power voltage, wherein the first power line may be disposed between the storage capacitor and the data line.

The display device may further include: a substrate; a first insulating layer, a second insulating layer, a third insulating layer, and a fourth insulating layer, sequentially disposed on the substrate; a second power line supplied with a second driving power voltage, which is different from the first driving power voltage; and an initialization power line supplied with initialization power voltage. The first power line may include a first vertical power line formed as a first conductive layer disposed on the substrate and a first horizontal power line formed as a second conductive layer disposed on the second insulating layer. In a plan view, the first vertical power line may be disposed between the storage capacitor of each of the first, second, and third sub-pixels and the data line.

Each of the first, second, and third sub-pixels may include: a light emitting element; a first transistor controlling a current of the light emitting element; a second transistor connected between the data line and a gate electrode of the first transistor, the second transistor being turned on by the scan signal; a third transistor connected between the initialization power line and a source electrode of the first transistor, the third transistor being turned on by the control signal; and the storage capacitor including a lower electrode electrically connected to the gate electrode of the first transistor and a source electrode of the second transistor and an upper electrode electrically connected to the source electrode of the first transistor and a source electrode of the third transistor.

The first, second, and third transistors may be disposed at a side of the storage capacitor.

The second power line may include a second vertical power line formed as the first conductive layer and a second horizontal power line formed as the second conductive layer.

In a plan view, the storage capacitor may be disposed between the second vertical power line and the first vertical power line.

In a plan view, the initialization power line may be disposed between the first vertical power line and the data line.

The gate electrode of the first transistor of each of the first, second, and third sub-pixels may be disposed between the storage capacitor and the first vertical power line.

The lower electrode may be disposed on the substrate, and the upper electrode may be disposed on the first insulating layer to overlap the lower electrode with the first insulating layer interposed between the lower electrode and the upper electrode.

The upper electrode and an active pattern layer of each of the first, second, and third transistors may be disposed on a same layer.

The upper electrode may be integral with the source electrode of the first transistor and the source electrode of the third transistor.

The light emitting element may include: a first electrode formed as a third conductive layer disposed on the fourth insulating layer; a light emitting layer disposed on the first electrode; and a second electrode disposed on the light emitting layer.

The first electrode may be electrically connected to the source electrode of the first transistor through a contact part passing through the second to fourth insulating layers.

In a plan view, the initialization power line may be disposed between the second vertical power line and the storage capacitor.

In a plan view, the initialization power line may be disposed at a first side of the storage capacitor, and the first vertical power line may be disposed at a second side of the storage capacitor.

In a plan view, the third transistor among the first, second, and third transistors may be disposed at the first side of the storage capacitor, and the first and second transistors among the first, second, and third transistors may be disposed at the second side of the storage capacitor.

Each of the first, second, and third sub-pixels may further include: an encapsulation layer disposed over the light emitting element; a color filter layer disposed on the encapsulation layer; and an overcoat layer disposed over the color filter layer.

In an embodiment, a display device may include: a substrate; first, second, third, and fourth insulating layers sequentially stacked on the substrate; first, second, and third sub-pixels each including a pixel circuit including a storage capacitor and first, second, and third transistors, which are disposed on the substrate, and a light emitting element electrically connected to the pixel circuit; a scan line disposed on the substrate, the scan line selectively transferring a scan signal and a control signal to each of the first, second, and third sub-pixels; a data line transferring a data signal to each of the first, second, and third sub-pixels; a first power line supplied with a first power voltage; a second power line supplied with a second power voltage, which is different from the first power voltage; and an initialization power line supplied with an initialization power voltage, which is different from the first and second power voltages. A gate electrode of the first transistor may be disposed between the storage capacitor and the first power line.

The first power line may include a first vertical power line disposed on the substrate and a first horizontal power line disposed on the second insulating layer. The first vertical power line may be disposed between the storage capacitor and the data line.

In a plan view, the first, second, and third transistors may be disposed at a side of the storage capacitor.

In a plan view, the storage capacitor may be disposed between the initialization power line and the first vertical power line.

### BRIEF DESCRIPTION OF THE DRAWINGS

Example embodiments will now be described more fully hereinafter with reference to the accompanying drawings; however, they may be implemented in different forms and should not be construed as limited to embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it may be the only element between the two elements, or one or more intervening elements may also be present. Like reference numerals refer to like elements throughout.

FIG. 1 is a schematic plan view illustrating a display device in accordance with an embodiment.

FIG. 2 is a schematic cross-sectional view illustrating a display panel shown in FIG. 1.

FIG. 3 is a schematic circuit diagram illustrating an electrical connection relationship of components included in each of pixels shown in FIG. 1.

FIGS. 4 and 5 are schematic plan views illustrating a pixel in accordance with an embodiment.

FIG. 6 is a schematic plan view illustrating only components included in a first conductive layer in the pixel shown in FIG. 5.

FIG. 7 is a schematic plan view illustrating only transistors and components included in a second conductive layer in the pixel shown in FIG. 5.

FIG. 8 is a schematic cross-sectional view taken along line I-I′ shown in FIG. 5.

FIGS. 9 and 10 are schematic cross-sectional views taken along line II-II′ shown in

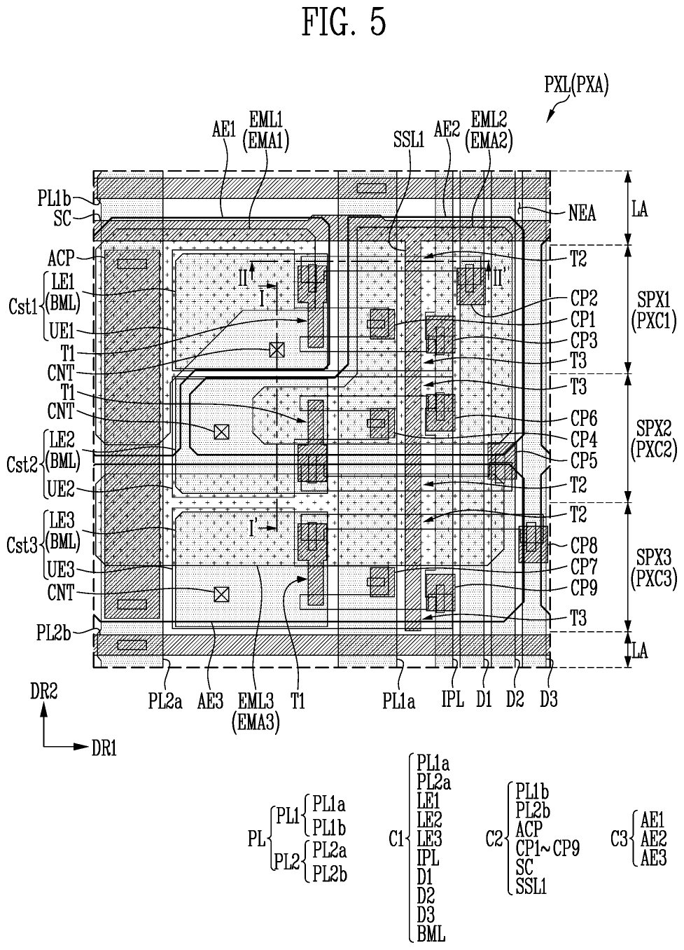

FIG. 5.

FIG. 11 illustrates a pixel in accordance with an embodiment, and is a schematic cross-sectional view taken along line I-I′ shown in FIG. 5.

FIG. 12 is a schematic plan view illustrating a pixel in accordance with an embodiment.

FIG. 13 is a schematic plan view illustrating only components included in a first conductive layer in the pixel shown in FIG. 12.

FIG. 14 is a schematic plan view illustrating only transistors and components included in a second conductive layer in the pixel shown in FIG. 12.

FIG. 15 is a schematic cross-sectional view taken along line III-III′ shown in FIG. 12.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein.

It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

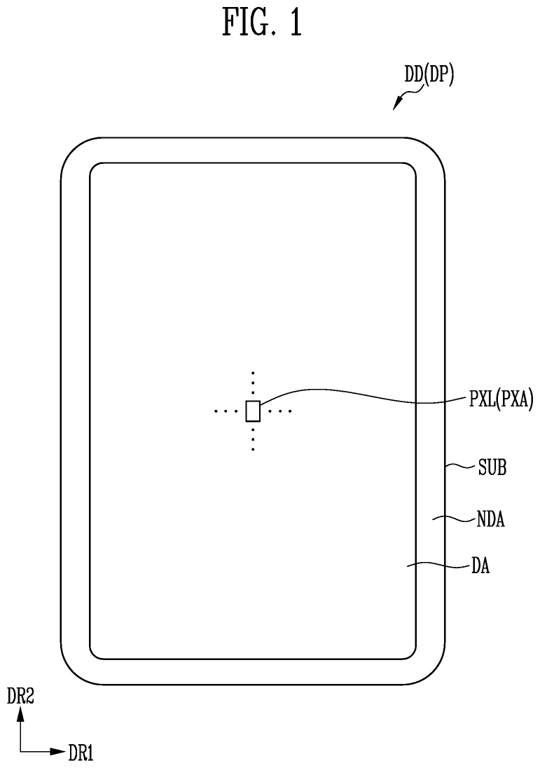

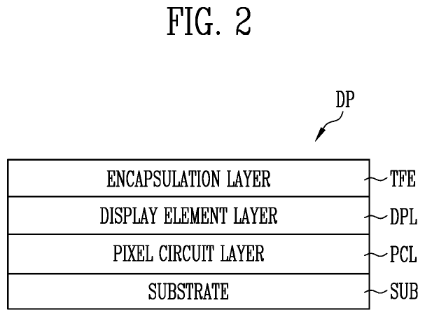

FIG. 1 is a schematic plan view illustrating a display device DD in accordance with an embodiment. FIG. 2 is a schematic cross-sectional view illustrating a display panel DP shown in FIG. 1.

In FIGS. 1 and 2, for convenience of description, a structure of the display device DD, for example, the display panel DP provided in the display device DD is illustrated based on a display area DA in which an image is displayed.

Referring to FIGS. 1 and 2, the display panel DP (or the display device DD) in accordance with an embodiment may be provided in various shapes. For example, the display panel DP may be provided in a rectangular plate shape having two pairs of sides parallel to each other. However, embodiments are not limited thereto. In case that the display panel DP is provided in the rectangular plate shape, any one pair of sides among the two pairs of sides may be provided longer than the other pair of sides.

At least a portion of the display panel DP may have flexibility, and be folded at the portion having the flexibility. However, embodiments are not limited thereto.

The display panel DP may display an image. A self-luminescent display panel, such as an Organic Light Emitting Display panel (OLED panel) using an organic light emitting diode as a light emitting element, a micro-LED or nano-LED display panel using a micro-LED or nano-LED as a light emitting element, or a Quantum Dot Organic Light Emitting Display panel (QD OLED panel) using a quantum dot and an organic light emitting diode, may be used as the display panel DP. For example, a non-self-luminescent display panel, such as a Liquid Crystal Display panel (LCD panel), an Electro-Phoretic Display panel (EPD panel), or an Electro-Wetting Display panel (EWD panel), may be used as the display panel DP. In case that a non-self-luminescent display panel is used as the display panel DP, the display device DD may include a backlight unit for supplying light to the display panel DP. In an embodiment, the display panel DP may be an organic light emitting display panel.

The display panel DP may include a substrate SUB and pixels PXL formed on the substrate SUB.

The substrate SUB may include a transparent insulating material to enable light to be transmitted therethrough, but embodiments are not limited thereto. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

An area of the substrate SUB may be provided as the display area DA such that the pixels PXL may be disposed therein, and another area on the substrate SUB may be provided as a non-display area NDA. For example, the substrate SUB may include the display area DA including pixel areas PXA in which the respective pixels PXL are disposed and the non-display area NDA disposed at the periphery of the display area DA (or adjacent to the display area DA).

The non-display area NDA may be disposed adjacent to the display area DA. The non-display area NDA may be provided at at least one side of the display area DA. For example, the non-display area NDA may surround a circumference (or edge portion) of the display area DA. A line part may be connected to each of the pixels PXL, and a driver may be connected to the line part and may drive the pixel PXL. The line part and the driver may be provided in the non-display area NDA.

Each of the pixels PXL may be provided in the display area DA of the substrate SUB. Each of the pixels PXL may include a light emitting element emitting white light and/or colored light and a pixel circuit for driving the light emitting element. The pixel circuit may include at least one transistor connected (e.g., electrically connected) to the light emitting element.

Each pixel PXL may emit light of one color among red, green, and blue, but embodiments are not limited thereto. Each pixel PXL may emit light of one color among cyan, magenta, yellow, and white.

Pixels PXL may be provided to be arranged in a matrix form along rows extending in a first direction DR1 and columns extending in a second direction DR2 intersecting the first direction DR1. However, the arrangement form of the pixels PXL is not limited, and the pixels PXL may be arranged in various forms. In some embodiments, in case that pixels PXL are provided, the pixels PXL may be provided to different areas (or sizes). For example, in case that pixels PXL have different colors of lights emitted therefrom, the pixels PXL may be provided to have different areas (or sizes) or different shapes with respect to the different colors.

The driver may provide a certain signal and a certain voltage to each pixel PXL through the line part, thereby controlling driving of the pixel PXL.

The display panel DP (or each of the pixels PXL) may include a pixel circuit layer PCL, a display element layer DPL, and an encapsulation layer TFE, which are disposed on the substrate SUB.

The pixel circuit layer PCL may be formed on the substrate SUB, and include a transistor and signal lines connected to the transistor. For example, the transistor may have a form in which an active pattern layer (or semiconductor layer), a gate electrode, a source electrode, and a drain electrode may be sequentially stacked with an insulating layer interposed therebetween. The semiconductor pattern layer may include amorphous silicon, poly-silicon, low temperature poly-silicon, an organic semiconductor, and/or an oxide semiconductor. The gate electrode, the source electrode, and the drain electrode may include one of aluminum (Al), copper (Cu), titanium (Ti), and molybdenum (Mo), but embodiments are not limited thereto. For example, the pixel circuit layer PCL may include at least one insulating layer.

The display element layer DPL may be disposed on the pixel circuit layer PCL. The display element layer DPL may include a light emitting element emitting light. The light emitting element may be, for example, an organic light emitting diode, but embodiments are not limited thereto. In some embodiments, the light emitting element may be an inorganic light emitting element including an inorganic light emitting material or a light emitting element emitting light by changing a wavelength of light emitted, by using a quantum dot.

The encapsulation layer TFE may be selectively disposed on the display element layer DPL. The encapsulation layer TFE may be an encapsulation substrate or have the form of an encapsulation film provided as a multi-layer. In case that the encapsulation layer TFE has the form of the encapsulation film, the encapsulation layer TFE may include an inorganic layer and/or an organic layer. For example, the encapsulation layer TFE may have a form in which an inorganic layer, an organic layer, and an inorganic layer are sequentially stacked. The encapsulation layer TFE may prevent external air and moisture from infiltrating (or permeating) into the display element layer DPL and the pixel circuit layer PCL.

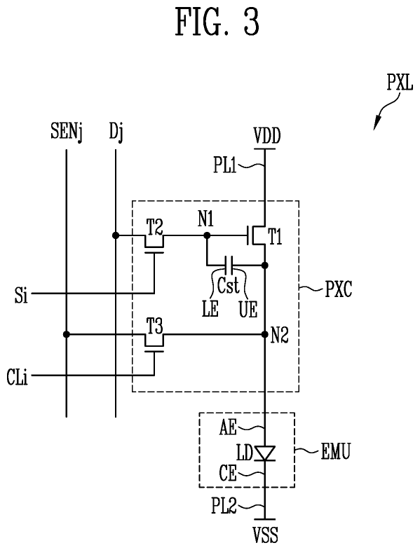

FIG. 3 is a schematic circuit diagram illustrating an electrical connection relationship of components included in each of the pixels PXL shown in FIG. 1.

For convenience of description, a pixel PXL disposed on an i-th pixel row (or i-th horizontal line) and a j-th pixel column will be illustrated in FIG. 3 (here, i and j are natural numbers).

Referring to FIGS. 1 to 3, the pixel PXL may include an emission component EMU which generates light with a luminance corresponding to a data signal. For example, the pixel PXL may further include a pixel circuit PXC for driving the emission component EMU.

The emission component EMU may include a light emitting element LD connected between a first power line PL1 supplied with a first driving power voltage VDD and a second power line PL2 supplied with a second driving power voltage VSS. For example, the emission component EMU may include a light emitting element LD including a first electrode AE connected to the first driving power voltage VDD via the pixel circuit PXC and the first power line PL1 and a second electrode CE connected to the second driving power voltage VSS via the second power line PL2. The first electrode AE may be an anode, and the second electrode CE may be a cathode. The first driving power voltage VDD and the second driving power voltage VSS may have different potentials. A potential difference between the first and second driving power voltages VDD and VSS may be set equal to or higher than a threshold voltage of the light emitting element LD during an emission period of the pixel PXL.

In case that a pixel PXL (or sub-pixel) is disposed on an i-th pixel row and a j-th pixel column in the display area DA, a pixel circuit PXC of the pixel PXL (or sub-pixel) may be connected (e.g., electrically connected) to an i-th scan line Si and a j-th data line Dj. For example, the pixel circuit PXC may be connected (e.g., electrically connected) to an i-th control line CLi and a j-th sensing line SENj.

The above-described pixel circuit PXC may include first to third transistors T1, T2, and T3 and a storage capacitor Cst.

The first transistor T1 may be a driving transistor for controlling a driving current applied to the light emitting element LD, and may be connected (e.g., electrically connected) between the first driving power voltage VDD and the light emitting element LD. For example, a first terminal of the first transistor T1 may be connected (e.g., electrically connected) to the first driving power voltage VDD through the first power line PL1, a second terminal of the first transistor T1 may be connected (e.g., electrically connected) to a second node N2, and a gate electrode of the first transistor T1 may be connected (e.g., electrically connected) to a first node N1. The first transistor T1 may control an amount of driving current applied from the first driving power voltage VDD to the light emitting element LD through the second node N2 according to a voltage applied to the first node N1. In an embodiment, the first terminal of the first transistor T1 may be a drain electrode, and the second terminal of the first transistor T1 may be a source electrode. However, embodiments are not limited thereto. In some embodiments, the first terminal may be the source electrode, and the second terminal may be the drain electrode.

The second transistor T2 may be a switching transistor which selects a pixel PXL in response to a scan signal and may activate the pixel PXL, and may be connected (e.g., electrically connected) between a data line Dj (e.g., the j-th data line) and the first node N1. A first terminal of the second transistor T2 may be connected (e.g., electrically connected) to the data line Dj, a second terminal of the second transistor T2 may be connected (e.g., electrically connected) to the first node N1 (or the gate electrode of the first transistor T1), and a gate electrode of the second transistor T2 may be connected (e.g., electrically connected) to a scan line Si (or the i-th scan line). The first terminal and the second terminal of the second transistor T2 may be different terminals. For example, in case that the first terminal is a drain electrode, the second terminal may be a source electrode.

The second transistor T2 may be turned on in case that a scan signal having a gate-on voltage (e.g., a high level voltage) is supplied from the scan line Si, to electrically connect the data line Dj and the first node N1 to each other. The first node N1 may be a point at which the second terminal of the second transistor T2 and the gate electrode of the first transistor T1 are connected to each other, and the second transistor T2 may transfer a data signal to the gate electrode of the first transistor T1.

The third transistor T3 may electrically connect the first transistor T1 to a sensing line SENj (e.g., the j-th sensing line), to acquire a sensing signal through the sensing line SENj, and detect a characteristic of the pixel PXL, including a threshold voltage of the first transistor T1, and the like, by using the sensing signal. Information on the characteristic of the pixel PXL may be used to convert image data such that a characteristic deviation between pixels PXL may be compensated. A second terminal of the third transistor T3 may be connected (e.g., electrically connected) to the second terminal of the first transistor T1, a first terminal of the third transistor T3 may be connected (e.g., electrically connected) to the sensing line SENj, and a gate electrode of the third transistor T3 may be connected (e.g., electrically connected) to a control line CLi (e.g., the i-th control line). The first terminal may be a drain electrode, and the second terminal may be a source electrode.

The third transistor T3 may be an initialization transistor capable of initializing the second node N2, and may be turned on in case that a sensing control signal is supplied from the control line CLi, to transfer an initialization power voltage to the second node N2. Accordingly, the storage capacitor Cst connected (e.g., electrically connected) to the second node N2 may be initialized.

The storage capacitor Cst may include a lower electrode LE (or first storage electrode) and an upper electrode UE (or second storage electrode). The lower electrode LE may be connected (e.g., electrically connected) to the first node N1, and the upper electrode UE may be connected (e.g., electrically connected) to the second node N2. The storage capacitor Cst may charge a data voltage corresponding to a data signal supplied to the first node N1 during one frame period. Accordingly, the storage capacitor Cst may store a voltage corresponding to a difference between a voltage of the gate electrode of the first transistor T1 and a voltage of the second node N2.

Although an embodiment in which the first to third transistors T1, T2, and T3 are all N-type transistors has been disclosed in FIG. 3, embodiments are not limited thereto. For example, at least one of the above-described first to third transistors T1, T2, and T3 may be replaced with a P-type transistor.

The structure of the pixel circuit PXC may be variously modified and implemented.

In the following embodiment, for convenience of description, a lateral direction (e.g., X-axis direction or horizontal direction) on a plane is indicated as a first direction DR1, a longitudinal direction (e.g., Y-axis direction or vertical direction) on the plane is indicated as a second direction DR2, and a longitudinal direction on a section is indicated as a third direction DR3.

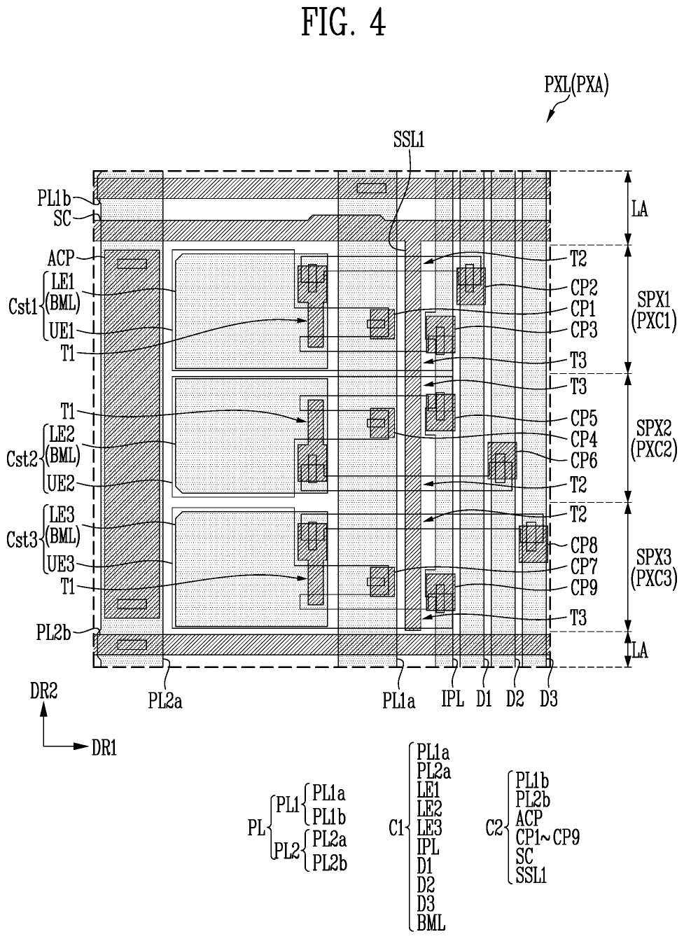

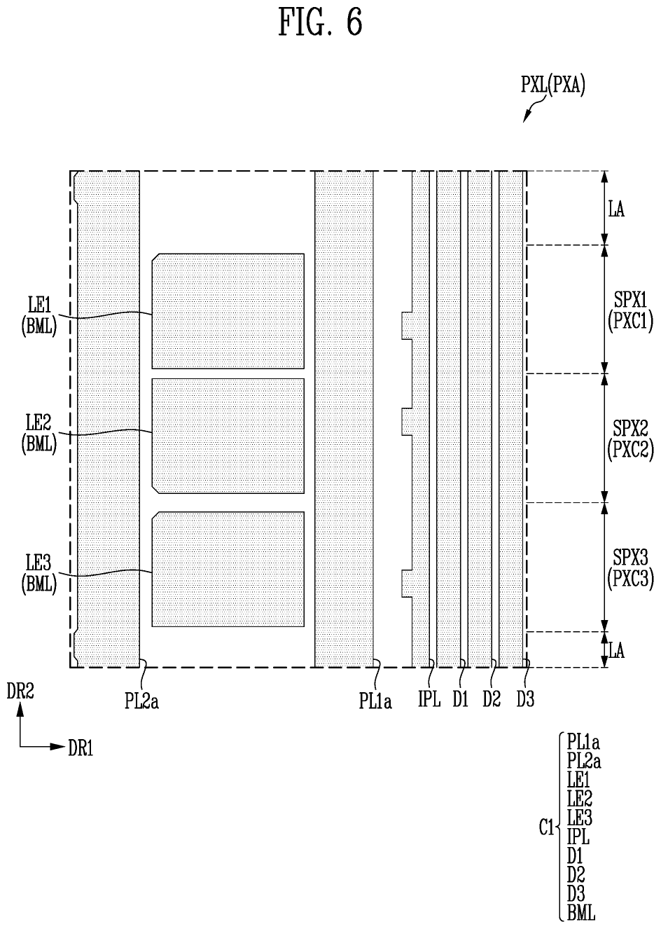

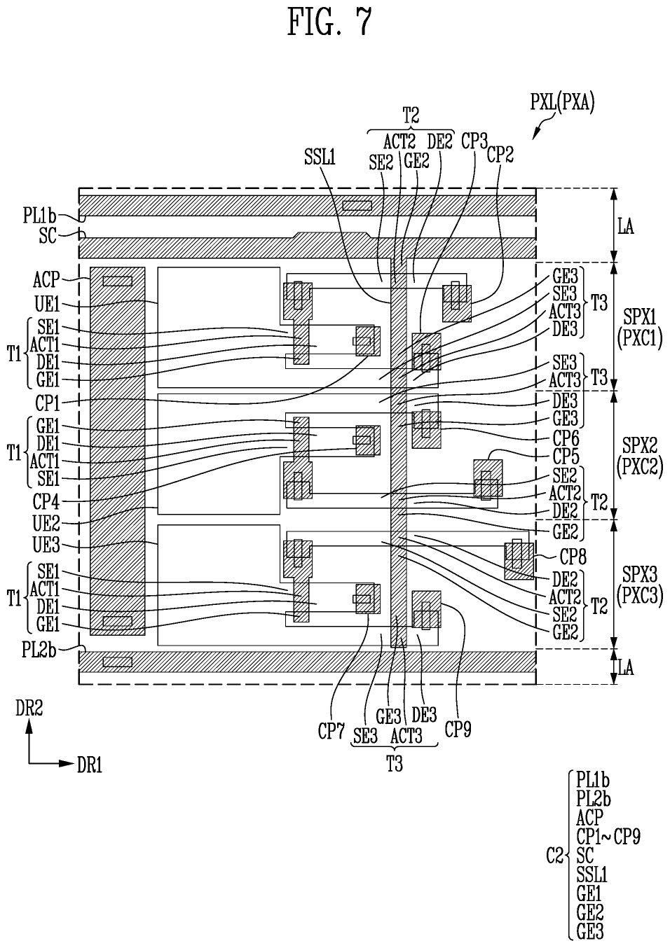

FIGS. 4 and 5 are schematic plan views illustrating a pixel PXL in accordance with an embodiment. FIG. 6 is a schematic plan view illustrating only components included in a first conductive layer C1 in the pixel PXL shown in FIG. 5. FIG. 7 is a schematic plan view illustrating only transistors T1, T2, and T3 and components included in a second conductive layer C2 in the pixel PXL shown in FIG. 5.

In the pixel PXL shown in FIG. 5, a first emission area EMA1 of a first sub-pixel SPX1, a second emission area EMA2 of a second sub-pixel SPX2, and a third emission area EMA3 of a third sub-pixel SPX3 are additionally illustrated in the pixel PXL shown in FIG. 4.

Referring to FIGS. 1 to 7, the pixel PXL in accordance with an embodiment may be disposed in a pixel area PXA as an area of the display area DA. The pixel area PXA (or the display area DA) may include a line area LA. For example, the line area LA may be disposed between two pixels PXL arranged adjacent to each other on the same pixel column. In an embodiment, the line area LA may be an area in which signal lines extending in the first direction DR1 are disposed. For example, a first horizontal power line PL1b, a scan line SC, and a second horizontal power line PL2b, which extend in the first direction DR1 (or horizontal direction) may be disposed in the line area LA, but embodiments are not limited thereto.

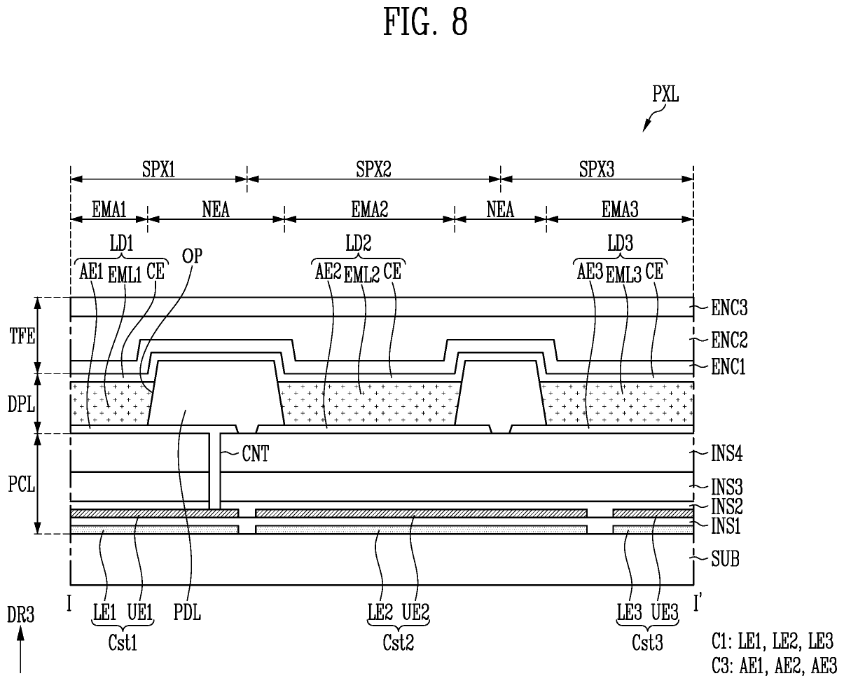

The pixel PXL may include a first sub-pixel SPX1, a second sub-pixel SPX2, and a third sub-pixel SPX3. The first sub-pixel SPX1 may include a first pixel circuit PXC1 and a first light emitting element (see “LD1” shown in FIG. 8) driven by the first pixel circuit PXC1. The second sub-pixel SPX2 may include a second pixel circuit PXC2 and a second light emitting element (see “LD2” shown in FIG. 8) driven by the second pixel circuit PXC2. The third sub-pixel SPX3 may include a third pixel circuit PXC3 and a third light emitting element (see “LD3” shown in FIG. 8) driven by the third pixel circuit PXC3. Each of the first to third pixel circuits PXC1, PXC2, and PXC3 may be the pixel circuit PXC described with reference to FIG. 3, and each of the first to third light emitting elements LD1, LD2, and LD3 may be the light emitting element LD described with reference to FIG. 3.

The pixel area PXA may include a first emission area EMA1, a second emission area EMA2, and a third emission area EMA3. For example, the pixel area PXA may include a non-emission area NEA surrounding the first to third emission areas EMA1, EMA2, and EMA3. A pixel defining layer (see “PDL” shown in FIG. 8) which defines the first to third emission areas EMA1, EMA2, and EMA3 may be disposed in the non-emission area NEA.

The first emission area EMA1 may be an area in which light is emitted from the first light emitting element LD1 of the first sub-pixel SPX1. For example, the first emission area EMA1 may correspond to an area in which a first light emitting layer EML1 of the first light emitting element LD1 is disposed.

The second emission area EMA2 may be an area in which light is emitted from the second light emitting element LD2 of the second sub-pixel SPX2. For example, the second emission area EMA2 may correspond to an area in which a second light emitting layer EML2 of the second light emitting element LD2 is disposed.

The third emission area EMA3 may be an area in which light is emitted from the third light emitting element LD3 of the third sub-pixel SPX3. For example, the third emission area EMA3 may correspond to an area in which a third light emitting layer EML3 of the third light emitting element LD3 is disposed.

Signal lines connected (e.g., electrically connected) to the first to third sub-pixels SPX1, SPX2, and SPX3 may be disposed in the pixel area PXA. For example, the scan line SC, data lines D1, D2, and D3, a power line PL, an initialization power line IPL, and the like may be disposed in the pixel area PXA, but embodiments are not limited thereto.

The scan line SC may be disposed in the line area LA and extend in the first direction DR1. The scan line SC may be selectively supplied with a scan signal and a sensing control signal. The scan line SC may be formed as a second conductive layer C2. The second conductive layer C2 may be formed as a single layer or a multi-layer, which includes molybdenum (Mo), copper (Cu), aluminum (Al), chromium (Cr), gold (Au), titanium (Ti), nickel (Ni), neodymium (Nd), indium (In), tin (Sn), and oxides or alloys thereof.

The scan line SC may include a first sub-scan line SSL1 extending in the second direction DR2. The first sub-scan line SSL1 may be formed as the second conductive layer C2, and be integral with the scan line SC. The first sub-scan line SSL1 may be an area of the scan line SC.

The first sub-scan line SSL1 may be integral with a second gate electrode GE2 of a second transistor T2 of each of the first to third pixel circuits PXC1, PXC2, and PXC3. For example, a portion of the first sub-scan line SSL1 may be the second gate electrode GE2 of the second transistor T2 of each of the first to third pixel circuits PXC1, PXC2, and PXC3.

For example, the first sub-scan line SSL1 may be integral with a third gate electrode GE3 of a third transistor T3 of each of the first to third pixel circuits PXC1, PXC2, and PXC3. For example, another portion of the first sub-scan line SSL1 may be the third gate electrode GE3 of the third transistor T3 of each of the first to third pixel circuits PXC1, PXC2, and PXC3.

The scan line SC may supply a scan signal to the second gate electrode GE2 of the second transistor T2 of each of the first to third pixel circuits PXC1, PXC2, and PXC3 during a driving period of a light emitting element LD, and supply a sensing control signal to the third gate electrode GE3 of the third transistor T3 of each of the first to third pixel circuits PXC1, PXC2, and PXC3.

The data lines D1, D2, and D3 may include a first data line D1, a second data line D2, and a third data line D3, which extend in the second direction DR2 and are arranged in the first direction DR1. Each of the first to third data lines D1, D2, and D3 may be supplied with a data signal.

The first data line D1 may be connected (e.g., electrically connected) to a second transistor T2 of the first pixel circuit PXC1 (or the first sub-pixel SPX1), the second data line D2 may be connected (e.g., electrically connected) to a second transistor T2 of the second pixel circuit PXC2 (or the second sub-pixel SPX2), and the third data line D3 may be connected (e.g., electrically connected) to a second transistor T2 of the third pixel circuit PXC3 (or the third sub-pixel SPX3). Each of the first, second, and third data lines D1, D2, and D3 may be formed as a first conductive layer C1. The first conductive layer C1 may include the same material as the above-described second conductive layer C2, or include an appropriate (or selected) material among the materials as examples of the material of the second conductive layer C2. However, embodiments are not limited thereto.

The power line PL may include a first power line PL1 and a second power line PL2.

The first power line PL1 may be supplied with the first driving power voltage VDD. The first power line PL1 may include a first vertical power line PL1a and the first horizontal power line PL1b.

The first vertical power line PL1a may extend along the second direction DR2, and be disposed between first to third storage capacitors Cst1, Cst2, and Cst3 and the data lines D1, D2, and D3 in a plan view. For example, the first vertical power line PL1a may be disposed between the first to third storage capacitors Cst1, Cst2, and Cst3 and the initialization power line IPL adjacent to the first data line D1. The first vertical power line PL1a may be formed as the first conductive layer C1. The first vertical power line PL1a may be connected (e.g., electrically connected) to the first horizontal power line PL1b disposed in a layer different from a layer of the first vertical power line PL1a through a corresponding contact hole.

The first horizontal power line PL1b may be disposed in the line area LA, and extend in the first direction DR1. The first horizontal power line PL1b may be formed as the second conductive layer C2. The first vertical power line PL1a formed as the first conductive layer C1 and the first horizontal power line PL1b formed as the second conductive layer C2 may be connected (e.g., electrically connected) to each other through the corresponding contact hole. The first power line PL1 may have a mesh structure due to the first vertical power line PL1a and the first horizontal power line PL1b, which are connected (e.g., electrically connected) to each other.

The second power line PL2 may be supplied with the second driving power voltage VSS. The second power line PL2 may include a second vertical power line PL2a and the second horizontal power line PL2b.

The second vertical power line PL2a may extend along the second direction DR2, and be disposed at a side (e.g., a left side) of the first to third storage capacitors Cst1, Cst2, and Cst3 in a plan view. The second vertical power line PL2a may be formed as the first conductive layer C1. The second vertical power line PL2a may be connected (e.g., electrically connected) to an additional conductive pattern layer ACP disposed in a layer different from a layer of the second vertical power line PL2a through a corresponding contact hole.

The additional conductive pattern layer ACP may be formed as the second conductive layer C2, and extend in the second direction DR2 to overlap the second vertical power line PL2a. The second vertical power line PL2a may be connected (e.g., electrically connected) to the additional conductive pattern layer ACP disposed in the layer different from the layer of the second vertical power line PL2a through the corresponding contact hole, to be implemented in a double-layer structure. The line resistance of the second vertical power line PL2a may be reduced.

The second horizontal power line PL2b may be disposed in the line area LA, and extend in the first direction DR1. The second horizontal power line PL2b may be formed as the second conductive layer C2. The second vertical power line PL2a formed as the first conductive layer C1 and the second horizontal power line PL2b formed as the second conductive layer C2 may be connected (e.g., electrically connected) to each other through a corresponding contact hole. The second power line PL2 may have a mesh structure due to the second vertical power line PL2a and the second horizontal power line PL2b, which are connected (e.g., electrically connected) to each other.

The initialization power line IPL may extend in the second direction DR2, and be formed as the first conductive layer C1. The initialization power line IPL may be disposed between the first vertical power line PL1a and the data lines D1, D2, and D3 in a plan view. The first vertical power line PL1a, the initialization power line IPL, and the data lines D1, D2, and D3 may be spaced apart from each other in the first direction DR1. The initialization power line IPL may be the sensing line SENj described with reference to FIG. 3. The initialization power line IPL may be supplied with the initialization power voltage. The initialization power line IPL may be connected (e.g., electrically connected) to a third transistor T3 of each of the first to third pixel circuits PXC1, PXC2, and PXC3 (or the first to third sub-pixels SPX1, SPX2, and SPX3).

The first pixel circuit PXC1 of the first sub-pixel SPX1, the second pixel circuit PXC2 of the second sub-pixel SPX2, and the third pixel circuit PXC3 of the third sub-pixel SPX3 may have structures substantially similar or identical to one another. Hereinafter, the first pixel circuit PXC1 will be described, and descriptions of the second pixel circuit PXC2 and the third sub-pixel PXC3 will be simplified.

The first pixel circuit PXC1 may include first to third transistors T1, T2, and T3 and a first storage capacitor Cst1.

The first transistor T1 may include a first gate electrode GE1, a first active pattern layer ACT1, a first source electrode SE1, and a first drain electrode DE1.

The first gate electrode GE1 may be connected (e.g., electrically connected) to a second source electrode SE2 of the second transistor T2 through a corresponding contact hole. The first gate electrode GE1 may be formed as the second conductive layer C2. In an embodiment, the first gate electrode GE1 may be connected (e.g., electrically connected) to a bottom metal pattern layer BML through a corresponding contact hole. In an embodiment, the first gate electrode GE1 may be disposed between the first storage capacitor Cst1 and the first vertical power line PL1a.

The bottom metal pattern layer BML (or first bottom metal pattern layer) may be formed as the first conductive layer C1, and overlap the first transistor T1. The bottom metal pattern layer BML may be connected (e.g., electrically connected) to the first gate electrode GE1 through the corresponding contact hole. As the bottom metal pattern layer BML is connected (e.g., electrically connected) to the first gate electrode GE1, floating of the bottom metal pattern layer BML may be prevented, and the line resistance of the first gate electrode GE1 may be reduced.

The first active pattern layer ACT1, the first source electrode SE1, and the first drain electrode DE1 may be formed as a semiconductor pattern layer made of poly-silicon, amorphous silicon, an oxide semiconductor, or the like. The first active pattern layer ACT1, the first source electrode SE1, and the first drain electrode DE1 may be formed with a semiconductor layer undoped or doped with an impurity. For example, the first source electrode SE1 and the first drain electrode DE1 may be doped with the impurity to have conductivity, and the first active pattern layer ACT1 may be formed as an intrinsic semiconductor layer undoped with the impurity.

The first active pattern layer ACT1 may be disposed on the bottom portion of the first gate electrode GE1 formed as the second conductive layer C2, thereby overlapping the first gate electrode GE1. The first active pattern layer ACT1 may form a channel region of the first transistor T1.

The first source electrode SE1 may be connected to an end portion of the first active pattern layer ACT1. The first source electrode SE1 may be doped with the impurity in an impurity doping process performed after the second conductive layer C2 is formed, to have conductivity. In an embodiment, the first source electrode SE1 may be integral with a third source electrode SE3 of the third transistor T3 to be connected to the third source electrode

The first drain electrode DE1 may be connected to another end portion of the first active pattern layer ACT1. The first drain electrode DE1 may be doped with the impurity in the impurity doping process performed after the second conductive layer C2 is formed, to have conductivity. The first drain electrode DE1 may be connected (e.g., electrically connected) to the first conductive pattern layer CP1 through a corresponding contact hole.

The first conductive pattern layer CP1 may be formed as the second conductive layer C2, and overlap the first drain electrode DE1 and the first vertical power line PL1a. A portion of the first conductive pattern layer CP1 may be connected (e.g., electrically connected) to the first drain electrode DE1 through a corresponding contact hole. Another portion of the first conductive pattern layer CP1 may be connected (e.g., electrically connected) to the first vertical power line PL1a through the contact hole. The first drain electrode DE1 and the first vertical power line PL1a may be connected (e.g., electrically connected) to each other through the first conductive pattern layer CP1.

The second transistor T2 may include a second gate electrode GE2, a second active pattern layer ACT2, the second source electrode SE2, and a second drain electrode DE2.

The second gate electrode GE2 may be integral with the first sub-scan line SSL1, and be formed as the second conductive layer C2. The second gate electrode GE2 may overlap the second active pattern layer ACT2.

The second active pattern layer ACT2, the second source electrode SE2, and the second drain electrode DE2 may be formed as a semiconductor pattern layer made of poly-silicon, amorphous silicon, an oxide semiconductor, or the like. The second source electrode SE2 and the second drain electrode DE2 may be doped with an impurity to have conductivity, and the second active pattern layer ACT2 may be formed as an intrinsic semiconductor layer undoped with the impurity.

The second active pattern layer ACT2 may be disposed on the bottom portion of the second gate electrode GE2, thereby overlapping the second gate electrode GE2. The second active pattern layer ACT2 may form a channel region of the second transistor T2.

The second source electrode SE2 may be connected to an end portion of the second active pattern layer ACT2. The second source electrode SE2 may be doped with the impurity in the impurity doping process performed after the second conductive layer C2 is formed, to have conductivity. The second source electrode SE2 may be connected (e.g., electrically connected) to the first gate electrode GE1 through a corresponding contact hole.

The second drain electrode DE2 may be connected to another end portion of the second active pattern layer ACT2. The second drain electrode DE2 may be doped with the impurity in the impurity doping process performed after the second conductive layer C2 is formed, to have conductivity. The second drain electrode DE2 may be connected (e.g., electrically connected) to the second conductive pattern layer CP2 through a corresponding contact hole.

The second conductive pattern layer CP2 may be formed as the second conductive layer C2, and overlap the first data line D1 and the second drain electrode DE2. A portion of the second conductive pattern layer CP2 may be connected (e.g., electrically connected) to the second drain electrode DE2 through a corresponding contact hole. Another portion of the second conductive pattern layer CP2 may be connected (e.g., electrically connected) to the first data line D1 through the contact hole. The second drain electrode DE2 and the first data line D1 may be connected (e.g., electrically connected) to each other through the second conductive pattern layer CP2.

The third transistor T3 may include a third gate electrode GE3, a third active pattern layer ACT3, the third source electrode SE3, and a third drain electrode DE3.

The third gate electrode GE3 may be formed as the second conductive layer C2, and be integral with the first sub-scan line SSL1. The third gate electrode GE3 may overlap the third active pattern layer ACT3.

The third active pattern layer ACT3, the third source electrode SE3, and the third drain electrode DE3 may be formed as a semiconductor pattern layer made of poly-silicon, amorphous silicon, an oxide semiconductor, or the like. The third source electrode SE3 and the third drain electrode DE3 may be doped with an impurity to have conductivity, and the third active pattern layer ACT3 may be formed as an intrinsic semiconductor layer undoped with the impurity.

The third active pattern layer ACT3 may overlap the third gate electrode GE3. The third active pattern layer ACT3 may form a channel region of the third transistor T3.

The third source electrode SE3 may be connected to an end portion of the third active pattern layer ACT3. The third source electrode SE3 may be doped with the impurity in the impurity doping process performed after the second conductive layer C2 is formed, to have conductivity. The third source electrode SE3 may be integral with the first source electrode SE1 to be connected to the first source electrode SE1. As the third source electrode SE3 and the first source electrode SE1 are integral, a separate first connection member for connecting the third source electrode SE3 and the first source electrode SE1 to each other may be omitted.

The third drain electrode DE3 may be connected to another end portion of the third active pattern layer ACT3. The second drain electrode DE2 may be doped with the impurity in the impurity doping process performed after the second conductive layer C2 is formed, to have conductivity. The third drain electrode DE3 may be connected (e.g., electrically connected) to a third conductive pattern layer CP3 through a corresponding contact hole.

The third conductive pattern layer CP3 may overlap the initialization power line IPL and the third drain electrode DE3. A portion of the third conductive pattern layer CP3 may be connected (e.g., electrically connected) to the third drain electrode DE3 through a corresponding contact hole. Another portion of the third conductive pattern layer CP3 may be connected (e.g., electrically connected) to the initialization power line IPL through the contact hole. The third drain electrode DE3 and the initialization power line IPL may be connected (e.g., electrically connected) to each other through the third conductive pattern layer CP3.

The first storage capacitor Cst1 may include a first lower electrode LE1 and a first upper electrode UE1. The first storage capacitor Cst1 may be the storage capacitor Cst described with reference to FIG. 3.

The first lower electrode LE1 may be formed as the first conductive layer C1, and be integral with the bottom metal pattern layer BML. The first lower electrode LE1 (or the bottom metal pattern layer BML) may be disposed between the second vertical power line PL2a and the first vertical power line PL1a in a plan view. In an embodiment, the first lower electrode LE1 may be connected (e.g., electrically connected) to the first gate electrode GE1 and the second source electrode SE2 through a corresponding contact hole.

The first upper electrode UE1 may be integral with the first source electrode SE1 and the third source electrode SE3 to be connected to the first source electrode SE1 and the third source electrode SE3. The first upper electrode UE1 may be formed as a semiconductor pattern layer made of poly-silicon, amorphous silicon, an oxide semiconductor, or the like, and have conductivity after an impurity is doped. The first upper electrode UE1 may overlap the first lower electrode LE1, and have a size (or area) similar to or greater than a size (or area) of the first lower electrode LE1. However, embodiments are not limited thereto.

In an embodiment, the first upper electrode UE1 may not overlap the first gate electrode GE1. In a plan view, the first upper electrode UE1 may be disposed between the second vertical power line PL2a and the first vertical power line PL1a.

The first source electrode SE1, the third source electrode SE3, and the first upper electrode UE1, which are integral in the first pixel circuit PXC1 having the above-described configuration, may be connected (e.g., electrically connected) to a (1-1)th electrode AE1 (or first anode) through a contact part CNT.

The (1-1)th electrode AE1 may be formed as a third conductive layer C3. The third conductive layer C3 and the second conductive layer C2 may include the same material. The third conductive layer C3 may include at least one appropriate material among the materials as examples of the material of the second conductive layer C2. However, embodiments are not limited thereto. The (1-1)th electrode AE1 may overlap some components, e.g., the first transistor T1 and the first storage capacitor Cst1 of the first pixel circuit PXC1. For example, the (1-1)th electrode AE1 may overlap some signal lines connected (e.g., electrically connected) to the first pixel circuit PXC1. In an embodiment, the (1-1)th electrode AE1 may overlap a first light emitting layer EML1 corresponding to the first emission area EMA1. In case that the first sub-pixel SPX1 is a red pixel, the first light emitting layer EML1 may emit red light, but embodiments are not limited thereto.

The second pixel circuit PXC2 may include first to third transistors T1, T2, and T3 and a second storage capacitor Cst2.

The first transistor T1 may include a first gate electrode GE1, a first active pattern layer ACT1, a first source electrode SE1, and a first drain electrode DE1.

The first gate electrode GE1 may be connected (e.g., electrically connected) to a second source electrode SE2 of the second transistor T2 through a corresponding contact hole. The first gate electrode GE1 may be formed as the second conductive layer C2, and be connected (e.g., electrically connected) to a bottom metal pattern layer BML (or a second lower electrode LE2) through the contact hole. In an embodiment, the first gate electrode GE1 may be disposed between the second storage capacitor Cst2 and the first vertical power line PL1a.

The bottom metal pattern layer BML (or second bottom metal pattern layer) may be formed as the first conductive layer C1, and overlap the first transistor T1. For example, the bottom metal pattern layer BML may be integral with the second lower electrode LE2 of the second storage capacitor Cst2.

The first active pattern layer ACT1 may overlap the first gate electrode GE1. The first active pattern layer ACT1 may form a channel region of the first transistor T1.

The first source electrode SE1 may be connected to an end portion of the first active pattern layer ACT1. In an embodiment, the first source electrode SE1 may be integral with a third source electrode SE3 of the third transistor T3 to be connected to the third source electrode SE3.

The first drain electrode DE1 may be connected to another end portion of the first active pattern layer ACT1. The first drain electrode DE1 may be connected (e.g., electrically connected) to a fourth conductive pattern layer CP4 through a corresponding contact hole.

The fourth conductive pattern layer CP4 may be formed as the second conductive layer C2, and overlap the first drain electrode DE1 and the first vertical power line PL1a. A portion of the fourth conductive pattern layer CP4 may be connected (e.g., electrically connected) to the first drain electrode DE1 through a corresponding contact hole. Another portion of the fourth conductive pattern layer CP4 may be connected (e.g., electrically connected) to the first vertical power line PL1a through the contact hole. The first drain electrode DE1 and the first vertical power line PL1a may be connected (e.g., electrically connected) to each other through the fourth conductive pattern layer CP4.

The second transistor T2 may include a second gate electrode GE2, a second active pattern layer ACT2, the second source electrode SE2, and a second drain electrode DE2.

The second gate electrode GE2 may be integral with the first sub-scan line SSL1, and be formed as the second conductive layer C2.

The second active pattern layer ACT2 may form a channel region of the second transistor T2.

The second source electrode SE2 may be connected to an end portion of the second active pattern layer ACT2. The second source electrode SE2 may be connected (e.g., electrically connected) to the first gate electrode GE1 through a corresponding contact hole.

The second drain electrode DE2 may be connected to another end portion of the second active pattern layer ACT2. The second drain electrode DE2 may be connected (e.g., electrically connected) to a fifth conductive pattern layer CP5 through a corresponding contact hole.

The fifth conductive pattern layer CP5 may be formed as the second conductive layer C2, and overlap the second data line D2 and the second drain electrode DE2. A portion of the fifth conductive pattern layer CP5 may be connected (e.g., electrically connected) to the second drain electrode DE2 through a corresponding contact hole. Another portion of the fifth conductive pattern layer CP5 may be connected (e.g., electrically connected) to the second data line D2 through the contact hole. The second drain electrode DE2 and the second data line D2 may be connected (e.g., electrically connected) to each other through the fifth conductive pattern layer CP5.

The third transistor T3 may include a third gate electrode GE3, a third active pattern layer ACT3, the third source electrode SE3, and a third drain electrode DE3.

The third gate electrode GE3 may be formed as the second conductive layer C2, and be integral with the first sub-scan line SSL1.

The third active pattern layer ACT3 may form a channel region of the third transistor T3.

The third source electrode SE3 may be connected to an end portion of the third active pattern layer ACT3. The third source electrode SE3 may be integral with the first source electrode SE1 to be connected to the first source electrode SE1. As the third source electrode SE3 and the first source electrode SE1 are integral with each other, a separate second connection member for connecting the third source electrode SE3 and the first source electrode SE1 to each other may be omitted.

The third drain electrode DE3 may be connected to another end portion of the third active pattern layer ACT3. The third drain electrode DE3 may be connected (e.g., electrically connected) to a sixth conductive pattern layer CP6 through a corresponding contact hole.

The sixth conductive pattern layer CP6 may be formed as the second conductive layer C2, and overlap the third drain electrode DE3 and the initialization power line IPL. A portion of the sixth conductive pattern layer CP6 may be connected (e.g., electrically connected) to the third drain electrode DE3 through a corresponding contact hole. Another portion of the sixth conductive pattern layer CP6 may be connected (e.g., electrically connected) to the initialization power line IPL through the contact hole. The third drain electrode DE3 and the initialization power line IPL may be connected (e.g., electrically connected) to each other through the sixth conductive pattern layer CP6.

The second storage capacitor Cst2 may include the second lower electrode LE2 and a second upper electrode UE2. The second storage capacitor Cst2 may be the storage capacitor Cst described with reference to FIG. 3.

The second lower electrode LE2 may be formed as the first conductive layer C1, and be integral with the bottom metal pattern layer BML. The second lower electrode LE2 (or the bottom metal pattern layer BML) may be disposed between the second vertical power line PL2a and the first vertical power line PL1a in a plan view. In an embodiment, the second lower electrode LE2 may be connected (e.g., electrically connected) to the first gate electrode GE1 and the second source electrode SE2 through a corresponding contact hole.

The second upper electrode UE2 may be integral with the first source electrode SE1 and the third source electrode SE3 to be connected to the first source electrode SE1 and the third source electrode SE3. The second upper electrode UE2 may overlap the second lower electrode LE2, and have a size (or area) similar to or greater than a size (or area) of the second lower electrode LE2. However, embodiments are not limited thereto.

In an embodiment, the second upper electrode UE2 may overlap the first gate electrode GE1. In a plan view, the second upper electrode UE2 may be disposed between the second vertical power line PL2a and the first vertical power line PL1a.

The first source electrode SE1, the third source electrode SE3, and the second upper electrode UE2, which are integral in the second pixel circuit PXC2 having the above-described configuration, may be connected (e.g., electrically connected) to a (1-2)th electrode AE2 (or second anode) through a contact part CNT.

The (1-2)th electrode AE2 may be formed as the third conductive layer C3. The (1-2)th electrode AE2 may overlap some components, e.g., the first transistor T1 and the second storage capacitor Cst2 of the second pixel circuit PXC2. For example, the (1-2)th electrode AE2 may overlap some signal lines connected (e.g., electrically connected) to the second pixel circuit PXC2. In an embodiment, the (1-2)th electrode AE2 may overlap the second light emitting layer EML2 corresponding to the second emission area EMA2. In case that the second sub-pixel SPX2 is a green pixel, the second light emitting layer EML2 may emit green light, but embodiments are not limited thereto.

The third sub-pixel PXC3 may include first to third transistors T1, T2, and T3 and a third storage capacitor Cst3.

The first transistor T1 may include a first gate electrode GE1, a first active pattern layer ACT1, a first source electrode SE1, and a first drain electrode DE1.

The first gate electrode GE1 may be connected (e.g., electrically connected) to a second source electrode SE2 of the second transistor T2 through a corresponding contact hole.

The first gate electrode GE1 may be formed as the second conductive layer C2, and be connected (e.g., electrically connected) to a bottom metal pattern layer BML (or a third lower electrode LE3) through the contact hole. In an embodiment, the first gate electrode GE1 may be disposed between the third storage capacitor Cst3 and the first vertical power line PL1a.

The bottom metal pattern layer BML (or third bottom metal pattern layer) may be formed as the first conductive layer C1, and overlap the first transistor T1. For example, the bottom metal pattern layer BML may be integral with the third lower electrode LE3 of the third storage capacitor Cst3.

The first active pattern layer ACT1 may overlap the first gate electrode GE1. The first active pattern layer ACT1 may form a channel region of the first transistor T1.

The first source electrode SE1 may be connected to an end portion of the first active pattern layer ACT1. In an embodiment, the first source electrode SE1 may be integral with a third source electrode SE3 of the third transistor T3 to be connected to the third source electrode SE3.

The first drain electrode DE1 may be connected to another end portion of the first active pattern layer ACT1. The first drain electrode DE1 may be connected (e.g., electrically connected) to a seventh conductive pattern layer CP7 through a corresponding contact hole.

The seventh conductive pattern layer CP7 may be formed as the second conductive layer C2, and overlap the first drain electrode DE1 and the first vertical power line PL1a. A portion of the seventh conductive pattern layer CP7 may be connected (e.g., electrically connected) to the first drain electrode DE through a corresponding contact hole. Another portion of the seventh conductive pattern layer CP7 may be connected (e.g., electrically connected) to the first vertical power line PL1a through the contact hole. The first drain electrode DE1 and the first vertical power line PL1a may be connected (e.g., electrically connected) to each other through the seventh conductive pattern layer CP7.

The second transistor T2 may include a second gate electrode GE2, a second active pattern layer ACT2, the second source electrode SE2, and a second drain electrode DE2.

The second gate electrode GE2 may be integral with the first sub-scan line SSL1, and be formed as the second conductive layer C2.

The second active pattern layer ACT2 may form a channel region of the second transistor T2.

The second source electrode SE2 may be connected to an end portion of the second active pattern layer ACT2. The second source electrode SE2 may be connected (e.g., electrically connected) to the first gate electrode GE1 through a corresponding contact hole.

The second drain electrode DE2 may be connected to another end portion of the second active pattern layer ACT2. The second drain electrode DE2 may be connected (e.g., electrically connected) to an eighth conductive pattern layer CP8 through a corresponding contact hole.

The eighth conductive pattern layer CP8 may be formed as the second conductive layer C2, and overlap the third data line D3 and the second drain electrode DE2. A portion of the eighth conductive pattern layer CP8 may be connected (e.g., electrically connected) to the second drain electrode DE2 through a corresponding contact hole. Another portion of the eighth conductive pattern layer CP8 may be connected (e.g., electrically connected) to the third data line D3 through the contact hole. The second drain electrode DE2 and the third data line D3 may be connected (e.g., electrically connected) to each other through the eighth conductive pattern layer CP8.

The third transistor T3 may include a third gate electrode GE3, a third active pattern layer ACT3, the third source electrode SE3, and a third drain electrode DE3.

The third gate electrode GE3 may be formed as the second conductive layer C2, and be integral with the first sub-scan line SSL1.

The third active pattern layer ACT3 may form a channel region of the third transistor T3.

The third source electrode SE3 may be connected to an end portion of the third active pattern layer ACT3. The third source electrode SE3 may be integral with the first source electrode SE1 to be connected to the first source electrode SE1. As the third source electrode SE3 and the first source electrode SE1 are integral with each other, a separate third connection member for connecting the third source electrode SE3 and the first source electrode SE1 to each other may be omitted.

The third drain electrode DE3 may be connected to another end portion of the third active pattern layer ACT3. The third drain electrode DE3 may be connected (e.g., electrically connected) to a ninth conductive pattern layer CP9 through a corresponding contact hole.

The ninth conductive pattern layer CP9 may be formed as the second conductive layer C2, and overlap the third drain electrode DE3 and the initialization power line IPL. A portion of the ninth conductive pattern layer CP9 may be connected (e.g., electrically connected) to the third drain electrode DE3 through a corresponding contact hole. Another portion of the ninth conductive pattern layer CP9 may be connected (e.g., electrically connected) to the initialization power line IPL through the contact hole. The third drain electrode DE3 and the initialization power line IPL may be connected (e.g., electrically connected) to each other through the ninth conductive pattern layer CP9.

The third storage capacitor Cst3 may include the third lower electrode LE3 and a third upper electrode UE3. The third storage capacitor Cst3 may be the storage capacitor Cst described with reference to FIG. 3.

The third lower electrode LE3 may be formed as the first conductive layer C1, and be integral with the bottom metal pattern layer BML. The third lower electrode LE3 (or the bottom metal pattern layer BML) may be disposed between the second vertical power line PL2a and the first vertical power line PL1a in a plan view. In an embodiment, the third lower electrode LE3 may be connected (e.g., electrically connected) to the first gate electrode GE1 and the second source electrode SE2 through a corresponding contact hole.

The third upper electrode UE3 may be integral with the first source electrode SE1 and the third source electrode SE3 to be connected to the first source electrode SE1 and the third source electrode SE3. The third upper electrode UE3 may overlap the third lower lower electrode LE3. electrode LE3, and have a size (or area) similar to or greater than a size (or area) of the third

In an embodiment, the third upper electrode UE3 may overlap the first gate electrode GE1. In a plan view, the third upper electrode UE3 may be disposed between the second vertical power line PL2a and the first vertical power line PL1a.

The first source electrode SE1, the third source electrode SE3, and the third upper electrode UE3, which are integral in the third pixel circuit PX3 having the above-described configuration, may be connected (e.g., electrically connected) to a (1-3)th electrode AE3 (or third anode) through a contact part CNT.

The (1-3)th electrode AE3 may be formed as the third conductive layer C3. The (1-3)th electrode AE3 may overlap some components, e.g., the first transistor T1 and the third storage capacitor Cst3 of the third pixel circuit PXC3. For example, the (1-3)th electrode AE3 may overlap some signal lines connected (e.g., electrically connected) to the third pixel circuit PXC3. In an embodiment, the (1-3)th electrode AE3 may overlap the third light emitting layer EML3 corresponding to the third emission area EMA3. In case that the third sub-pixel SPX3 is a blue pixel, the third light emitting layer EML3 may emit blue light, but embodiments are not limited thereto.

In the above-described embodiment, the first storage capacitor Cst1, the second storage capacitor Cst2, and the third storage capacitor Cst3 may be arranged along the second direction DR2, and be disposed on the same line. The first to third storage capacitors Cst1, Cst2, and Cst3 in the pixel area PXA may be disposed between the second vertical power line PL2a and the first vertical power line PL1a. For example, the second vertical power line PL2a may be disposed at a side (e.g., a left side) of the first to third storage capacitors Cst1, Cst2, and Cst3 in the pixel area PXA, and the first vertical power line PL1a may be disposed at another side (e.g., a right side) of the first to third storage capacitors Cst1, Cst2, and Cst3 in the pixel area PXA.

In case that the first vertical power line PL1a is disposed at the right side of the first to third storage capacitors Cst1, Cst2, and Cst3, a first transistor T1 of each of the first to third pixel circuits PXC1, PXC2, and PXC3, which is connected (e.g., electrically connected) to the first vertical power line PL1a, may be disposed at the right side of a storage capacitor of the corresponding pixel circuit. For example, the first transistor T1 of the first pixel circuit PXC1 may be disposed between the right side of the first storage capacitor Cst1 and the first vertical power line PL1a, the first transistor T1 of the second pixel circuit PXC2 may be disposed between the right side of the second storage capacitor Cst2 and the first vertical power line PL1a, and the first transistor T1 of the third pixel circuit PXC3 may be disposed between the right side of the third storage capacitor Cst3 and the first vertical power line PL1a. The first gate electrode GE1 of the first transistor T1 of the first pixel circuit PXC1 may be disposed between the right side of the first storage capacitor Cst1 and the first vertical power line PL1a, the first gate electrode GE1 of the first transistor T1 of the second pixel circuit PXC2 may be disposed between the right side of the second storage capacitor Cst2 and the first vertical power line PL1a, and the first gate electrode GE1 of the first transistor T1 of the third pixel circuit PXC3 may be disposed between the right side of the third storage capacitor Cst3 and the first vertical power line PL1a.

For example, in the above-described embodiment, the initialization power line IPL and the first to third data lines D1, D2, and D3, which are connected (e.g., electrically connected) to the first to third pixel circuits PXC1, PXC2, and PXC3, may be disposed at the right side of the first to third storage capacitors Cst1, Cst2, and Cst3, and be spaced apart from the first vertical power line PL1a. The second vertical power line PL2a, the first to third storage capacitors Cst1, Cst2, and Cst3, the first vertical power line PL1a, the initialization power line IPL, the first data line D1, the second data line D2, and the third data line D3 may be sequentially arranged along the first direction DR1 in the pixel area PXA.

In case that the initialization power line IPL is disposed at the right side of the first to third storage capacitors Cst1, Cst2, and Cst3, a third transistor T3 of each of the first to third pixel circuits PXC1, PXC2, and PXC3, which is connected (e.g., electrically connected) to the initialization power line IPL, may be disposed at the right side of a storage capacitor of the corresponding pixel circuit. For example, the third transistor T3 of the first pixel circuit PXC1 may be disposed between the right side of the first storage capacitor Cst1 and the initialization power line IPL, the third transistor T3 of the second pixel circuit PXC2 may be disposed between the right side of the second storage capacitor Cst2 and the initialization power line IPL, and the third transistor T3 of the third pixel circuit PXC3 may be disposed between the right side of the third storage capacitor Cst3 and the initialization power line IPL.

In case that the first data line D1 is disposed at the right side of the first to third storage capacitors Cst1, Cst2, and Cst3, the second transistor T2 of the first pixel circuit PXC1, which is connected (e.g., electrically connected) to the first data line D1, may be disposed at the right side of the first storage capacitor Cst1. In case that the second data line D2 is disposed at the right side of the first to third storage capacitors Cst1, Cst2, and Cst3, the second transistor T2 of the second pixel circuit PXC2, which is connected (e.g., electrically connected) to the second data line D2, may be disposed at the right side of the second storage capacitor Cst2. In case that the third data line D3 is disposed at the right side of the first to third storage capacitors Cst1, Cst2, and Cst3, the second transistor T2 of the third pixel circuit PXC3, which is connected (e.g., electrically connected) to the third data line D3, may be disposed at the right side of the third storage capacitor Cst3.

As described above, the first to third transistors T1, T2, and T3 of the first pixel circuit PXC1 may be disposed at the right side of the first storage capacitor Cst1, the first to third transistors T1, T2, and T3 of the second pixel circuit PXC2 may be disposed at the right side of the second storage capacitor Cst2, and the first to third transistors T1, T2, and T3 of the third pixel circuit PXC3 may be disposed at the right side of the third storage capacitor Cst3. In each of the first to third sub-pixels SPX1, SPX2, and SPX3, electrical connection between a first gate electrode GE1 and a second source electrode SE2 (or a corresponding data line) may be made at the right side of a storage capacitor of the corresponding sub-pixel. Accordingly, influence of the electrical connection between the first gate electrode GE1 and the second source electrode SE2 on each of the first to third storage capacitors Cst1, Cst2, and Cst3 may be reduced or prevented. In each of the first to third sub-pixels SPX1, SPX2, and SPX3, the area (or size) of a first gate electrode GE1 of a first transistor T1 may be decreased, and the area of a storage capacitor of the corresponding sub-pixel may be ensured by the decreased area (or size) of the first gate electrode GE1. For example, in the first sub-pixel SPX1, the area of the first gate electrode GE1 of the first transistor T1 may be decreased, and the area of the first lower electrode LE1 and the first upper electrode UE1 may be increased by the decreased area of the first gate electrode GE1, so that the overlapping area of the first lower electrode LE1 and the first upper electrode UE1 may be further ensured, thereby increasing the capacitance of the first storage capacitor Cst1. In the second sub-pixel SPX2, the area of the first gate electrode GE1 of the first transistor T1 may be decreased, and the area of the second lower electrode LE2 and the second upper electrode UE2 may be increased by the decreased area of the first gate electrode GE1, so that the overlapping area of the second lower electrode LE2 and the second upper electrode UE2 may be further ensured, thereby increasing the capacitance of the second storage capacitor Cst2. In the third sub-pixel SPX3, the area of the first gate electrode GE1 of the first transistor T1 may be decreased, and the area of the third lower electrode LE3 and the third upper electrode UE3 may be increased by the decreased area of the first gate electrode GE1, so that the overlapping area of the third lower electrode LE3 and the third upper electrode UE3 may be further ensured, thereby increasing the capacitance of the third storage capacitor Cst3.

In accordance with the above-described embodiment, the capacitance of each of the first to third storage capacitors Cst1, Cst2, and Cst3 may be increased, thereby improving the reliability of the pixel PXL (or the display device DD).

In accordance with the above-described embodiment, as a first source electrode SE1 of a first transistor T1 and a third source electrode SE3 of a third transistor are integral with each other in each of the first to third pixel circuits PXC1, PXC2, and PXC3, a connection member (e.g., a contact hole, a conductive pattern layer, and the like) for electrically connecting the first source electrode SE1 and the third source electrode SE3 may be omitted. Accordingly, the area of the first storage capacitor Cst1 in the first pixel circuit PXC1 may be further ensured, thereby increasing the capacitance of the first storage capacitor Cst1, the area of the second storage capacitor Cst2 in the second pixel circuit PXC2 may be further ensured, thereby increasing the capacitance of the second storage capacitor Cst2, and the area of the third storage capacitor Cst3 in the third pixel circuit PXC3 may be further ensured, thereby increasing the capacitance of the third storage capacitor Cst3.

In accordance with the above-described embodiment, as the first vertical power line PL1a may be disposed at the right side of the first to third storage capacitors Cst1, Cst2, and Cst3, first to third transistors T1, T2, T3 of each of the first to third pixel circuit PXC1, PXC2, and PXC3 may be disposed at the right side of a storage capacitor of the corresponding pixel circuit. The first to third transistors T1, T2, and T3 may be readily formed at the right side of each of the first to third storage capacitors Cst1, Cst2, and Cst3, so that design constraints according to the position of the first to third transistors T1, T2, and T3 may be reduced.

Hereinafter, a stacked structure (or sectional structure) of the pixel PXL in accordance with the above-described embodiment will be described with reference to FIGS. 8 to 10.

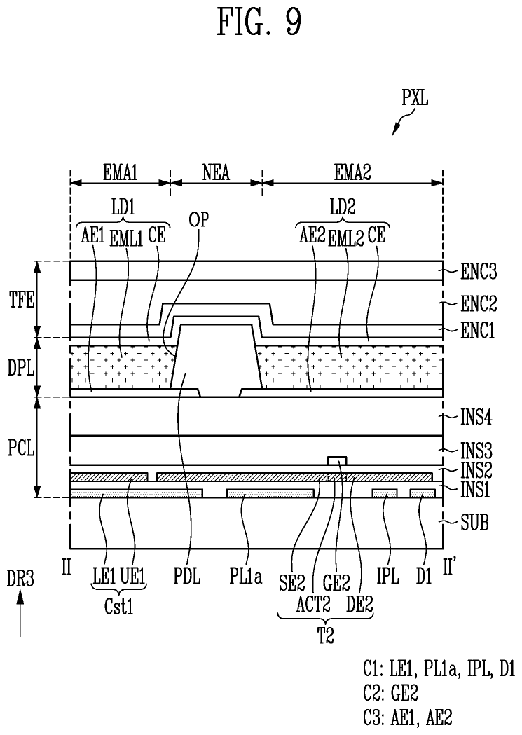

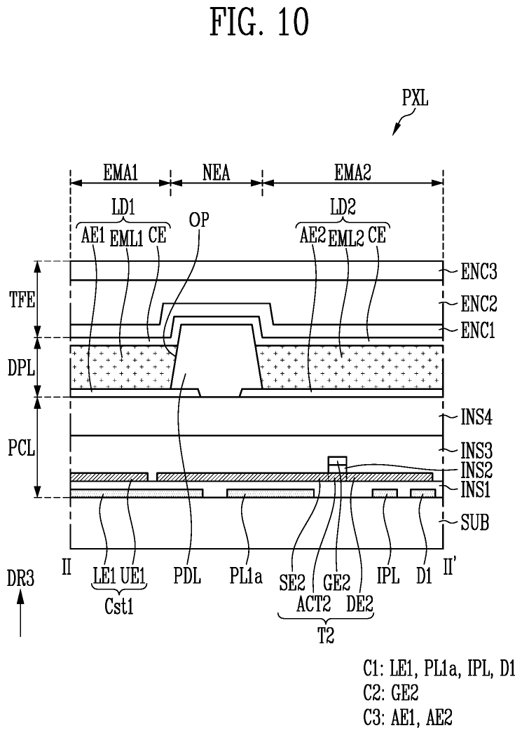

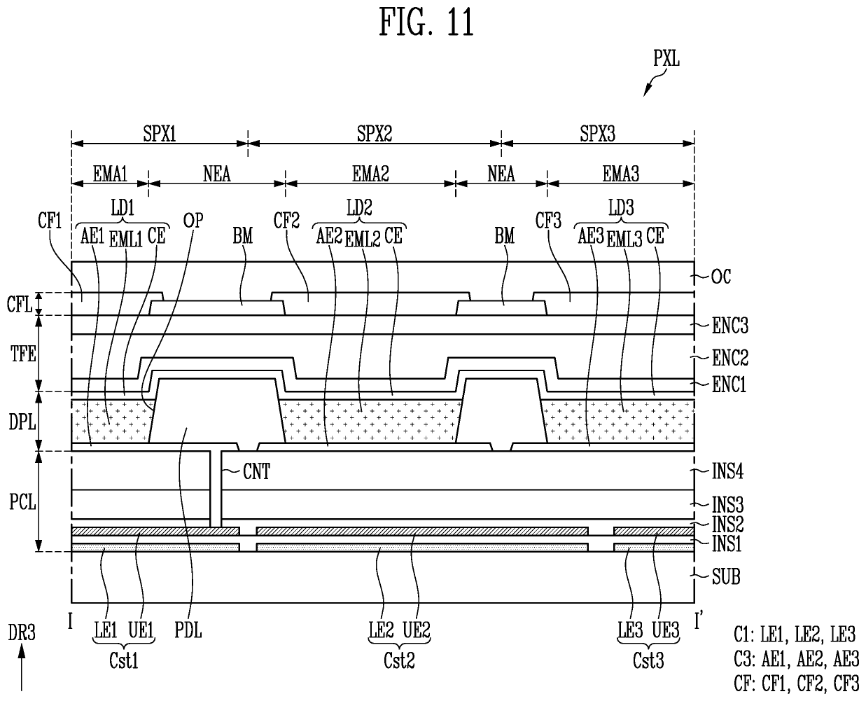

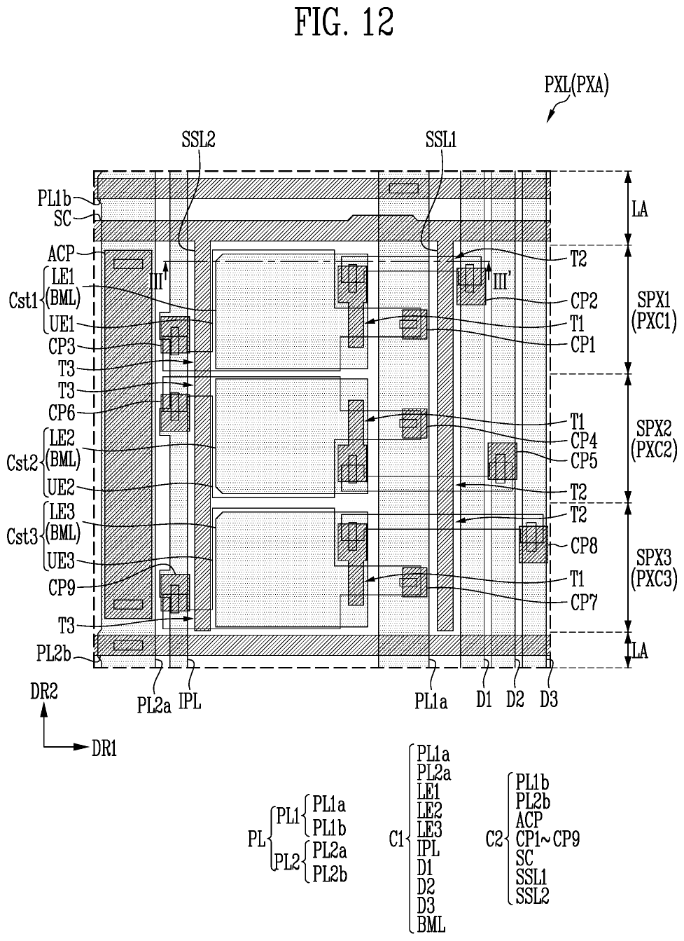

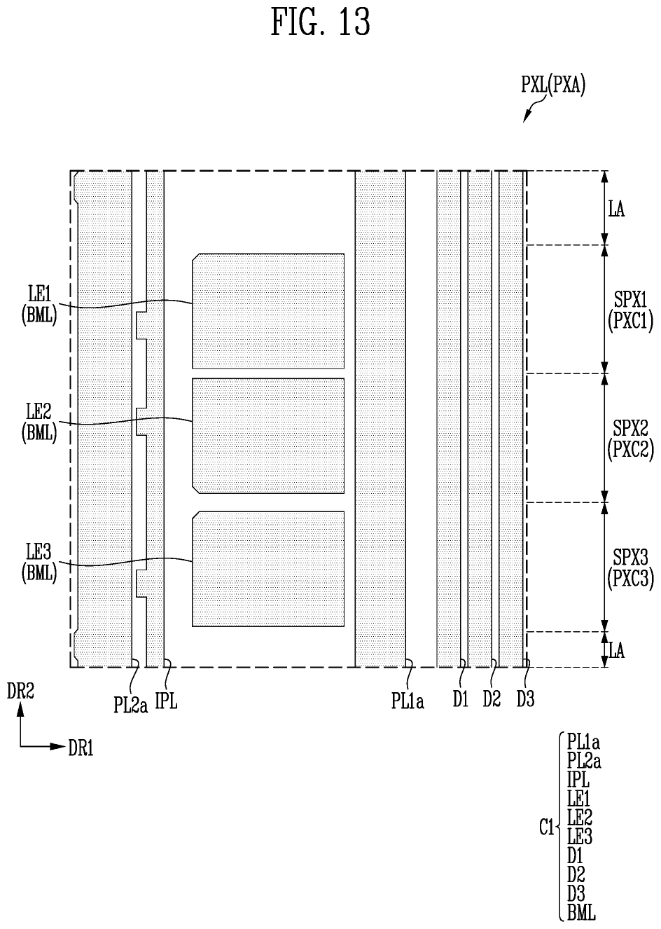

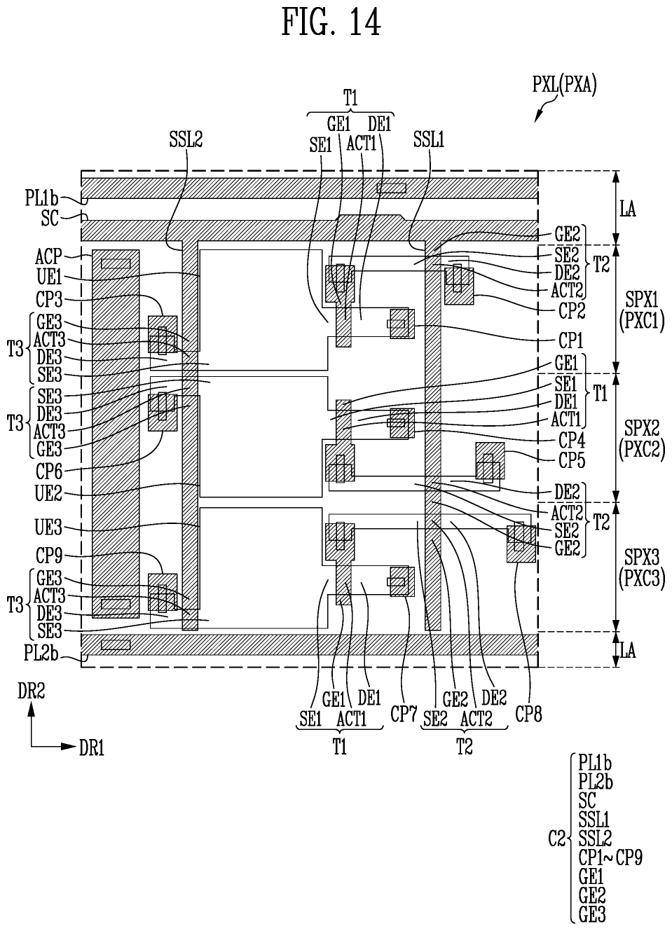

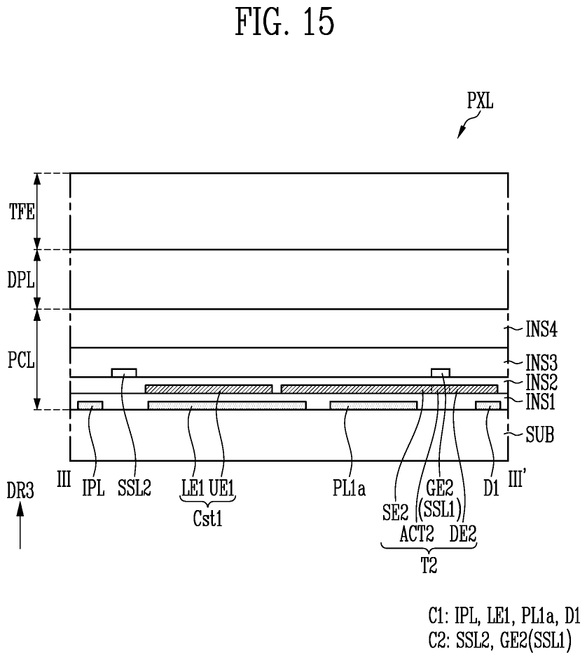

FIG. 8 is a schematic cross-sectional view taken along line I-I′ shown in FIG. 5. FIGS. 9 and 10 are schematic cross-sectional views taken along line II-II′ shown in FIG. 5.

FIG. 10 illustrates a modified example of an embodiment shown in FIG. 9 in relation to the position of a second insulating layer INS2, and the like.

In FIGS. 8 to 10, a stacked structure of the pixel PXL may be simplified and illustrated, such as that each electrode is illustrated as an electrode having a signal layer and each insulating layer is illustrated as an insulating layer provided as a single layer, but embodiments are not limited thereto.

In relation to embodiments shown in FIGS. 8 to 10, portions different from those of the above-described embodiment will be described to avoid redundancy.

Referring to FIGS. 1 to 10, the pixel PXL in accordance with an embodiment may include a first sub-pixel SPX1, a second sub-pixel SPX2, and a third sub-pixel SPX3, which are adjacent to each other.

The first sub-pixel SPX1 may include a first emission area EMA1 and a non-emission area NEA surrounding the first emission area EMA1. The second sub-pixel SPX2 may include a second emission area EMA2 and a non-emission area NEA surrounding the second emission area EMA2. The third sub-pixel SPX3 may include a third emission area EMA3 and a non-emission area NEA surrounding the third emission area EMA3.

Each of the first to third sub-pixels SPX1, SPX2, and SPX3 may include a substrate SUB, a pixel circuit layer PCL, a display element layer DPL, and an encapsulation layer TFE.

The substrate SUB may include a transparent insulating material that transmits light therethrough. The substrate SUB may be a rigid substrate or a flexible substrate.

Circuit elements (e.g., first to third transistors T1, T2, and T3) and signal lines connected (e.g., electrically connected) to the circuit elements may be disposed in the pixel circuit layer PCL. A light emitting element (see “LD” shown in FIG. 3) connected (e.g., electrically connected) to circuit elements of each of the first to third sub-pixels SPX1, SPX2, and SPX3 may be disposed in the display element layer DPL.

At least one insulating layer may be disposed on the substrate SUB. For example, a first insulating layer INS1, a second insulating layer INS2, a third insulating layer INS3, and a fourth insulating layer INS4, which are sequentially stacked along the third direction DR3, may be disposed on the substrate SUB. For example, at least one conductive layer may be disposed on the substrate SUB. For example, the conductive layer may include a first conductive layer C1 disposed between the substrate SUB and the first insulating layer INS1, a second conductive layer C2 disposed on the second insulating layer INS2, and a third conductive layer C3 disposed on the fourth insulating layer INS4.

The first conductive layer C1 may include a first vertical power line PL1a, a second vertical power line PL2a, an initialization power line IPL, first to third data lines D1, D2, and D3, a bottom metal pattern layer BML, and first to third lower electrodes LE1, LE2, and LE3. The second conductive layer C2 may include a first horizontal power line PL1b, a second horizontal power line PL2b, an additional conductive pattern layer ACP, first to ninth conductive pattern layers CP1 to CP9, first to third gate electrodes GE1, GE2, and GE3, a scan line SC, and a first sub-scan line SSL1. The third conductive layer C3 may include a (1-1)th electrode AE1, a (1-2)th electrode AE2, and a (1-3)th electrode AE3.

The pixel circuit layer PCL may be disposed on the substrate SUB. The above-described first to fourth insulating layers INS1, INS2, INS3, and INS4 may be disposed in the pixel circuit layer PCL.

The first insulating layer INS1 (or buffer layer) may be disposed (e.g., entirely disposed) on the substrate SUB. The first insulating layer INS1 may prevent an impurity from being diffused into the first to third transistors T1, T2, and T3. The first insulating layer INS1 may be an inorganic insulating layer including an inorganic material. The first insulating layer INS1 may include at least one of silicon nitride (SiNₓ), silicon oxide (SiOₓ), and silicon oxynitride (SiOₓN_{y}), or include at least one of metal oxides such as aluminum oxide (AlOₓ). The first insulating layer INS1 may be provided as a single layer, but be provided as a multi-layer including at least two layers. In case that the first insulating layer INS1 is provided as the multi-layer, the layers may be formed of the same material or be formed of different materials. The first insulating layer INS1 may be omitted according to a material of the substrate SUB, a process condition, and the like.

The second insulating layer INS2 (or gate insulating layer) may be disposed (e.g., entirely disposed) on the first insulating layer INS1. The second insulating layer INS2 may include the same material as the above-described first insulating layer INS1, or include an appropriate (or selected) material among the materials as examples of the material of the first insulating layer INS1. For example, the second insulating layer INS2 may include an inorganic insulting layer including an inorganic material. In an embodiment, the second insulating layer INS2 may be disposed (e.g., partially disposed) on the first insulating layer as shown in FIG. 10. For example, the second insulating layer INS2 may be etched together with a base material of the second conductive layer C2 in a manufacturing process of the second conductive layer C2, to be disposed only on the bottom portion of the second conductive layer C2. The second insulating layer INS2 may have the same width as the second conductive layer C2 disposed on the top thereof, but embodiments are not limited thereto.

The third insulating layer INS3 (or interlayer insulating layer) may be provided and/or formed (e.g., entirely provided and/or formed) on the second insulating layer INS2. The third insulating layer INS3 may include the same material as the first insulating layer INS1, or include an appropriate (or selected) material among the materials as examples of the material of the first insulating layer INS1. For example, the third insulating layer INS3 may be an inorganic insulating layer including an inorganic material.

The fourth insulating layer INS4 (or via layer) may be provided and/or formed (e.g., entirely provided and/or formed) on the third insulating layer INS3. The fourth insulating layer INS4 may be an inorganic insulating layer including an inorganic material or an organic insulating layer including an organic material. The inorganic insulating layer may include, for example, at least one of silicon nitride (SiNₓ), silicon oxide (SiOₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In an embodiment, the fourth insulating layer INS4 may be an organic insulating layer including an organic material.

Each of the above-described second to fourth insulating layers INS2, INS3, and INS4 may be partially opened to include a contact part CNT (or contact hole). The contact part CNT may be a connection point for electrically connecting a light emitting element LD of each of the first to third sub-pixels SPX1, SPX2, and SPX3 to each of first to third pixel circuits PXC1, PXC2, and PXC3

A pixel circuit layer PCL of each of the first to third sub-pixels SPX1, SPX2, and SPX3 may include first to third transistors T1, T2, and T3 and a storage capacitor, which are disposed on the first insulating layer INS1. For example, a pixel circuit layer PCL of the first sub-pixel SPX1 may include first to third transistors T1, T2, and T3 and a first storage capacitor Cst1, which are disposed on the first insulating layer INS1. A pixel circuit layer PCL of the second sub-pixel SPX2 may include first to third transistors T1, T2, and T3 and a second storage capacitor Cst2, which are disposed on the first insulating layer INS1. A pixel circuit layer PCL of the third sub-pixel SPX3 may include first to third transistors T1, T2, and T3 and a third storage capacitor Cst3, which are disposed on the first insulating layer INS1.

The first transistor T1 may include a first active pattern layer ACT1, a first source electrode SE1, and a first drain electrode DE1, which are disposed on the first insulating layer INS1, and a first gate electrode GE1 disposed on the second insulating layer INS2. A bottom metal pattern layer BML may be disposed on the bottom portion of the first transistor T1. The bottom metal pattern layer BML may be formed as the first conductive layer C1 disposed between the substrate SUB and the first insulating layer INS1, and be integral with a correspond lower electrode among first to third lower electrodes LE1, LE2, and LE3.

The second transistor T2 may include a second active pattern layer ACT2, a second source electrode SE2, and a second drain electrode DE2, which are disposed on the first insulating layer INS1, and a second gate electrode GE2 disposed on the second insulating layer INS2.

The third transistor T3 may include a third active pattern layer ACT3, a third source electrode SE3, and a third drain electrode DE3, which are disposed on the first insulating layer INS1, and a third gate electrode GE3 disposed on the second insulating layer INS2.

The first storage capacitor Cst1 may include a first lower electrode LE1 disposed between the substrate SUB and the first insulating layer INS1 and a first upper electrode UE1 overlapping the first lower electrode LE1 with the first insulating layer INS1 interposed between the first lower electrode LE1 and the first upper electrode UE1. The first lower electrode LE1 may be formed as the first conductive layer C1, and the first upper electrode UE1 may be formed as a semiconductor pattern layer which is disposed between the first insulating layer INS1 and the second insulating layer INS2 and is doped with an impurity to have conductivity. In the first sub-pixel SPX1, the first lower electrode LE1 may be integral with the bottom metal pattern layer BML, and the first upper electrode UE1 may be integral with the first source electrode SE1 and the third source electrode SE3. The first upper electrode UE1 may be connected (e.g., electrically connected) to a partial component, e.g., a (1-1)th electrode AE1 of the display element layer DPL through a corresponding contact part CNT.

The second storage capacitor Cst2 may include a second lower electrode LE2 disposed between the substrate SUB and the first insulating layer INS1 and a second upper electrode UE2 overlapping the second lower electrode LE2 with the first insulating layer INS1 interposed between the second lower electrode LE2 and the second upper electrode UE2. The second lower electrode LE2 may be formed as the first conductive layer C1, and the second upper electrode UE2 may be formed as a semiconductor pattern layer which is disposed between the first insulating layer INS1 and the second insulating layer INS2 and is doped with an impurity to have conductivity. In the second sub-pixel SPX2, the second lower electrode LE2 may be integral with a bottom metal pattern layer BML, and the second upper electrode UE2 may be integral with the first source electrode SE1 and the third source electrode SE3. The second upper electrode UE2 may be connected (e.g., electrically connected) to a partial component, e.g., a (1-2)th electrode AE2 of the display element layer DPL through a corresponding contact part CNT.

The third storage capacitor Cst3 may include a third lower electrode LE3 disposed between the substrate SUB and the first insulating layer INS1 and a third upper electrode UE3 overlapping the third lower electrode LE3 with the first insulating layer INS1 interposed between the third lower electrode LE3 and the third upper electrode UE3. The third lower electrode LE3 may be formed as the first conductive layer C1, and the third upper electrode UE3 may be formed as a semiconductor pattern layer which is disposed between the first insulating layer INS1 and the second insulating layer INS2 and is doped with an impurity to have conductivity. In the third sub-pixel SPX3, the third lower electrode LE3 may be integral with a bottom metal pattern layer BML, and the third upper electrode UE3 may be integral with the first source electrode SE1 and the third source electrode SE3. The third upper electrode UE3 may be connected (e.g., electrically connected) to a partial component, e.g., a (1-3)th electrode AE3 of the display element layer DPL through a corresponding contact part CNT.

The third insulating layer INS3 and the fourth insulating layer INS4 may be consecutively provided and/or formed over the first to third transistors T1, T2, and T3 and the first storage capacitors Cst1, Cst2, and Cst3, which are described above.

The display element layer DPL may be provided and/or formed on the fourth insulating layer INS4.

The display element layer DPL may include a first light emitting element LD1, a second light emitting element LD2, a third light emitting element LD3, and a pixel defining layer PDL. The first light emitting element LD1 may be disposed in the display element layer DPL of the first sub-pixel SPX1, and be connected (e.g., electrically connected) to the first pixel circuit PXC1. The second light emitting element LD2 may be disposed in the display element layer DPL of the second sub-pixel SPX2, and be connected (e.g., electrically connected) to the second pixel circuit PXC2. The third light emitting element LD3 may be disposed in the display element layer DPL of the third sub-pixel SPX3, and be connected (e.g., electrically connected) to the third pixel circuit PXC3. Each of the first to third light emitting elements LD1, LD2, and LD3 may be the light emitting element LD described with reference to FIG. 3.

The first light emitting element LD1 may include the (1-1)th electrode AE1, a first light emitting layer EML1, and a second electrode CE. The second light emitting element LD2 may include the (1-2)th electrode AE2, a second light emitting layer EML2, and a second electrode CE. The third light emitting element LD3 may include the (1-3)th electrode AE3, a third light emitting layer EML3, and a second electrode CE.

The (1-1)th electrode AE1, the (1-2)th electrode AE2, and the (1-3)th electrode AE3 may be formed as the third conductive layer C3 provided and/or formed on the fourth insulating layer INS4 of a corresponding sub-pixel. The (1-1)th electrode AE1, the (1-2)th electrode AE2, and the (1-3)th electrode AE3 may be spaced apart from each other on the fourth insulating layer INS4. The (1-1)th electrode AE1 may be an anode of the first light emitting element LD1, the (1-2)th electrode AE2 may be an anode of the second light emitting element LD2, and the (1-3)th electrode AE3 may be an anode of the third light emitting element LD3.

The (1-1)th electrode AE1 may be connected (e.g., electrically connected) to the first upper electrode UE1 of the first storage capacitor Cst1 through a corresponding contact part CNT. The (1-2)th electrode AE2 may be connected (e.g., electrically connected) to the second upper electrode UE2 of the second storage capacitor Cst2 through a corresponding contact part CNT. The (1-3)th electrode AE3 may be connected (e.g., electrically connected) to the third upper electrode UE3 of the third storage capacitor Cst3 through a corresponding contact part CNT.

Each of the (1-1)th electrode AE1, the (1-2)th electrode AE2, and the (1-3)th electrode AE3 may be formed as a conductive material (or substance). The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of each of the (1-1)th electrode AE1, the (1-2)th electrode AE2, and the (1-3)th electrode AE3 is not limited to the above-described embodiment. In some embodiments, the (1-1)th electrode AE1, the (1-2)th electrode AE2, and the (1-3)th electrode AE3 may include a transparent conductive material (or substance). The transparent conductive material (or substance) may include a conductive oxide such as indium tin oxide (ITO), indium zinc oxide (IZO), zinc oxide (ZnO), indium gallium zinc oxide (IGZO), or indium tin zinc oxide (ITZO), a conductive polymer such as poly(3,4-ethylenedioxythiophene) (PEDOT), and the like. In case that the (1-1)th electrode AE1, the (1-2)th electrode AE2, and the (1-3)th electrode AE3 include a transparent conductive material (or substance), a separate conductive layer may be added, which is formed of an opaque metal for reflecting light emitted from the first, second, and third light emitting layers EML1, EML2, and EML3 in an image display direction of the display device DD (or an upper direction of the encapsulation layer TFE).

The (1-1)th electrode AE1 may be disposed in at least the first emission area EMA1, the (1-2)th electrode AE2 may be disposed in at least the second emission area EMA2, and the (1-3)th electrode AE3 may be disposed in at least the third emission area EMA3.

The pixel defining layer PDL may be formed on the pixel circuit layer PCL in the non-emission area NEA, and define (or partition) the first emission area EMA1, the second emission area EMA2, and the third emission area EMA3. The pixel defining layer PDL may include an organic insulating layer made of an organic material. The organic material may include acrylic resin, epoxy resin, phenolic resin, polyamide resin, polyimide resin, and the like. In some embodiments, the pixel defining layer PDL may include a light absorption material or have a light absorber coated thereon, to absorb light introduced from the outside. For example, the pixel defining layer PDL may include a carbon-based black pigment. However, embodiments are not limited thereto.

The pixel defining layer PDL may be partially opened to include an opening OP exposing an area of each of the (1-1)th electrode AE1, the (1-2)th electrode AE2, and the (1-3)th electrode AE3, and protrude in the third direction DR3 from the fourth insulating layer INS4 along the circumference of each of the first to third emission areas EMA1, EMA2, and EMA3.

The first light emitting layer EML1 may be disposed on the (1-1)th electrode AE1 exposed by an opening OP of the pixel defining layer PDL, the second light emitting layer EML2 may be disposed on the (1-2)th electrode AE2 exposed by another opening OP of the pixel defining layer PDL, and the third light emitting layer EML3 may be disposed on the (1-3)th electrode AE3 exposed by still another opening OP of the pixel defining layer PDL.

The first light emitting layer EML1 may be disposed on only the (1-1)th electrode AE1 in an opening OP of the pixel defining layer PDL, the second light emitting layer EML2 may be disposed on only the (1-2)th electrode AE2 in another opening OP of the pixel defining layer PDL, and the third light emitting layer EML3 may be disposed on only the (1-3)th electrode AE3 in still another opening OP of the pixel defining layer PDL. Each of the first light emitting layer EML1, the second light emitting layer EML2, and the third light emitting layer EML3 may be supplied to an area of a corresponding sub-pixel (e.g., onto an area of a first electrode (see “AE” shown in FIG. 3) exposed by an opening OP of the pixel defining layer PDL) by using an inkjet printing method, or the like, but embodiments are not limited thereto.

Each of the first light emitting layer EML1, the second light emitting layer EML2, and the third light emitting layer EML3 may have a multi-layer thin film structure including a light generation layer which generates light. For example, the first light emitting layer EML1 may include a light generation layer which generates and emits light of red, the second light emitting layer EML2 may include a light generation layer which generates and emits light of green, and the third light emitting layer EML3 may include a light generation layer which generates and emits light of blue. However, embodiments are not limited thereto. In some embodiments, each of the first light emitting layer EML1, the second light emitting layer EML2, and the third light emitting layer EML3 may include a light generation layer which generates and emits light of white. A color conversion layer for converting the light of the white (or light of a first color) into light of a specific color (or light of a second color), and the like may be provided.

The second electrode CE may be provided and/or formed over the first light emitting layer EML1, the second light emitting layer EML2, the third light emitting layer EML3, and the pixel defining layer PDL.

The second electrode CE may be a common layer commonly provided in the first sub-pixel SPX1, the second sub-pixel SPX2, and the third sub-pixel SPX3. The second electrode CE may be provided in a plate shape throughout the entire area of the display area DA, but embodiments are not limited thereto.

The second electrode CE may be a thin metal layer having a thickness to a degree to which light emitted from each of the first light emitting layer EML1, the second light emitting layer EML2, and the third light emitting layer EML3 may be transmitted therethrough. The second electrode CE may be formed of a metal material to have a relatively thin thickness or be formed of a transparent conductive material. For example, the second electrode CE may be formed as various transparent conductive materials. The second electrode CE may include at least one of various transparent conductive materials including indium tin oxide, indium zinc oxide, indium tin zinc oxide, aluminum zinc oxide, gallium zinc oxide, zinc tin oxide, and gallium tin oxide, and be formed to be substantially transparent or translucent to have a certain transmittance. Accordingly, light emitted from each of the first light emitting layer EML1, the second light emitting layer EML2, and the third light emitting layer EML3, which are disposed on the bottom portion of the second electrode CE, may be emitted upwardly from the encapsulation layer TFE with passing through the second electrode CE.

For example, the second electrode CE may be connected (e.g., electrically connected) to the second power line PL2.

The encapsulation layer TFE may be provided and/or formed (e.g., entirely provided and/or formed on the second electrode CE.

The encapsulation layer TFE may include first, second, and third encapsulation layers ENC1, ENC2, and ENC3 sequentially disposed on the second electrode CE. The first encapsulation layer ENC1 may be formed on the display element layer DPL (or the second electrode CE), and be disposed throughout the display area DA and at least a portion of the non-display area NDA. The second encapsulation layer ENC2 may be formed on the first encapsulation layer ENC1, and be disposed throughout the display area DA and at least a portion of the non-display area NDA. The third encapsulation layer ENC3 may be formed on the second encapsulation layer ENC2, and be disposed throughout the display area DA and at least a portion of the non-display area NDA. In some embodiments, the third encapsulation layer ENC3 may be disposed throughout the whole of the display area DA and the non-display area NDA.

Each of the first and third encapsulation layers ENC1 and ENC3 may be formed as an inorganic layer including an inorganic material, and the second encapsulation layer ENC2 may be formed as an organic layer including an organic material. The inorganic layer may include, for example, silicon nitride (SiNₓ), silicon oxide (SiOₓ), silicon oxynitride (SiOₓN_{y}), or the like. The organic layer may include an organic insulating material such as acrylic resin, epoxy resin, phenolic resin, polyamides resin, polyimides resin, polyester resin, poly-phenylene sulfide resin, or benzocyclobutene (BCB).

In some embodiments, a color filter layer and/or a color conversion layer for releasing light emitted from the first to third light emitting elements LD1, LD2, and LD3 as light having excellent color reproductivity may be selectively provided and/or formed on the encapsulation layer TFE.

FIG. 11 illustrates a pixel PXL in accordance with an embodiment, and is a schematic cross-sectional view taken along line I-I′ shown in FIG. 5.

In relation to the embodiment shown in FIG. 11, portions different from those of the above-described embodiment will be described to avoid redundancy.

Referring to 1 to 5 and 11, the pixel PXL in accordance with an embodiment may include a substrate SUB, a pixel circuit layer PCL, a display element layer DPL, an encapsulation layer TFE, a color filter layer CFL, and an overcoat layer OC.

The color filter layer CFL may be formed on the top portion of the encapsulation layer TFE through a continuous process. The color filter layer CFL may include a color filter CF and a light blocking pattern layer BM. The color filter CF may include a first color filter CF1, a second color filter CF2, and a third color filter CF3.

The first color filter CF1 may be disposed on a surface of a third encapsulation layer ENC3 of the encapsulation layer TFE to correspond to a first light emitting layer EML1. The second color filter CF2 may be disposed on the surface of the third encapsulation layer ENC3 of the encapsulation layer TFE to correspond to a second light emitting layer EML2. The third color filter CF3 may be disposed on the surface of the third encapsulation layer ENC3 of the encapsulation layer TFE to correspond to a third light emitting layer EML3.

The light blocking pattern layer BM may be disposed adjacent to the first to third color filters CF1, CF2, and CF3 on the surface of the third encapsulation layer ENC3 of the encapsulation layer TFE. For example, the light blocking pattern layer BM may be disposed on the surface of the third encapsulation layer ENC3 to corresponding to a pixel defining layer

PDL in a non-emission area NEA. The light blocking pattern layer BM may include a light blocking material. For example, the light blocking pattern layer BM may be a black matrix, but embodiments are not limited thereto. In some embodiments, the light blocking pattern layer BM may include at least one light blocking material and/or at least one reflective material that transmits light emitted from each of the first to third light emitting layers EML1, EML2, and EML3 to the image display direction of the display device DD, thereby improving light emission efficiency. The light blocking pattern layer BM may prevent color mixture of lights emitted from the first to third light emitting layers EML1, EML2, and EML3.

Each of the first, second, and third color filters CF1, CF2, and CF3 may include a colorant, such as a dye or a pigment, which absorbs wavelengths except for a corresponding color wavelength. The first color filter CF1 may be a red color filter, the second color filter CF2 may be a green color filter, and the third color filter CF3 may be a blue color filter. Although a case where adjacent color filters CF are spaced apart from each other with the light blocking pattern layer BM interposed between the adjacent color filters CF is illustrated in the drawing, the adjacent color filters CF may at least partially overlap each other on the light blocking pattern layer BM. In some embodiments, the first to third color filters CF1, CF2, and CF3 may be used as light blocking members overlapping each other in the non-emission area NEA to block light interference between adjacent sub-pixels. The light blocking pattern layer BM may be omitted.

The overcoat layer OC may be disposed over the above-described color filter layer CFL.

The overcoat layer OC may be disposed over the color filter layer CFL to cover a lower member including the color filter layer CFL. The overcoat layer OC may prevent external moisture, external air, or the like from infiltrating (or permeating) into the color filter layer CFL and damaging or contaminating the color filter layer CFL. For example, the overcoat layer OC may prevent a colorant of the color filter layer CFL from being diffused into another component. The overcoat layer OC may include an inorganic insulating layer including an inorganic material, but embodiments are not limited thereto.

FIG. 12 is a schematic plan view illustrating a pixel PXL in accordance with an embodiment. FIG. 13 is a schematic plan view illustrating only components included in a first conductive layer C1 in the pixel PXL shown in FIG. 12. FIG. 14 is a schematic plan view illustrating only transistors T1, T2, and T3 and components included in a second conductive layer C2 in the pixel PXL shown in FIG. 12. FIG. 15 is a schematic cross-sectional view taken along the line III-III′ shown in FIG. 12.

The embodiment shown in FIG. 12 illustrates a modified example shown in FIG. 4 in relation to the position of an initialization power line IPL1, and the like.

In relation to embodiments shown in FIGS. 12 to 15, portions different from those of the above-described embodiment will be described to avoid redundancy.

Referring to FIGS. 1 to 3 and 12 to 15, the pixel PXL in accordance with an embodiment may include a first sub-pixel SPX1 including a first pixel circuit PXC1, a second sub-pixel SPX2 including a second pixel circuit PXC2, and a third sub-pixel SPX3 including a third pixel circuit PXC3. Each of the first to third pixel circuits PXC1, PXC2, and PXC3 may include first to third transistors T1, T2, and T3 and a storage capacitor Cst.

Signal lines connected (e.g., electrically connected) to the first to third pixel circuits PXC1, PXC2, and PXC3 may be disposed in a pixel area PXA in which the pixel PXL is provided. For example, a scan line SC, first to third data lines D1, D2, and D3, a power line PL, and an initialization power line IPL may be disposed in the pixel area PXA.

The scan line SC may be formed as a second conductive layer C2 which extend along the first direction DR1 and is disposed on a second insulating layer INS2. The scan line SC may include first and second sub-scan lines SSL1 and SSL2 extending in the second direction DR2. The first sub-scan line SSL1 may be integral with a second gate electrode GE2 of a second transistor T2 of each of the first to third pixel circuits PXC1, PXC2, and PXC3. The second sub-scan line SSL2 may be integral with a third gate electrode GE3 of a third transistor T3 of each of the first to third pixel circuits PXC1, PXC2, and PXC3.

The first data line D1 may be connected (e.g., electrically connected) to a second transistor T2 of the first pixel circuit PXC1, the second data line D2 may be connected (e.g., electrically connected) to a second transistor T2 of the second pixel circuit PXC2, and the third data line D3 may be connected (e.g., electrically connected) to a second transistor T2 of the third pixel circuit PXC3.

The power line PL may include a first power line PL1 and a second power line PL2. The first power line PL1 may include a first vertical power line PL1a and a first horizontal power line PL1b, which are disposed in different layers and are connected (e.g., electrically connected) to each other through a corresponding contact hole. The second power line PL2 may include a second vertical power line PL2a and a second horizontal power line PL2b, which are disposed in different layers and are connected (e.g., electrically connected) to each other through a corresponding contact hole. In an embodiment, the first vertical power line PL1a may be disposed between first to third storage capacitors Cst1, Cst2, and Cst3 and the first data line D1.

The initialization power line IPL may be disposed between the second vertical power line PL2a and the first to third storage capacitors Cst1, Cst2, and Cst3 in a plan view. The second vertical power line PL2a may be disposed at a side (e.g., a left side) of the initialization power line IPL, and each of the first to third storage capacitors Cst1, Cst2, and Cst3 may be disposed at another side (e.g., a right side) of the initialization power line IPL.

In an embodiment, the first storage capacitor Cst1, the second storage capacitor Cst2, and the third storage capacitor Cst3 may be arranged along the second direction DR2, and be disposed on the same line. The first to third storage capacitors Cst1, Cst2, and Cst3 may be disposed between the initialization power line IPL and the first vertical power line PL1a. The initialization power line IPL may be disposed at a side (e.g., a left side) of the first to third storage capacitors Cst1, Cst2, and Cst3, and the first vertical power line PL1a may be disposed at another side (e.g., a right side) of the first to third storage capacitors Cst1, Cst2, and Cst3.

In case that the first vertical power line PL1a is disposed at the right side of the first to third storage capacitors Cst1, Cst2, and Cst3, a first transistor T1 of each of the first to third pixel circuits PXC1, PXC2, and PXC3, which is connected (e.g., electrically connected) to the first vertical power line PL1a, may be disposed at the right side of a storage capacitor of the corresponding pixel circuit. In an embodiment, the first to third data lines D1, D2, and D3 may be disposed at a side (e.g., a right side) of the first vertical power line PL1a to be spaced apart from the first vertical power line PL1a along the first direction DR1. In case that each of the first to third data lines D1, D2, and D3 is disposed at the right side of the first vertical power line PL1a, the second transistor T2 of the first pixel circuit PXC1, which is connected (e.g., electrically connected) to the first data line D1, the second transistor T2 of the second pixel circuit PXC2, which is connected (e.g., electrically connected) to the second data line D2, and the second transistor T2 of the third pixel circuit PXC3, which is connected (e.g., electrically connected) to the third data line D3, may be disposed at the right side of the storage capacitor of the corresponding pixel circuit.

In case that the initialization power line IPL is disposed at the left side of the first to third storage capacitors Cst1, Cst2, and Cst3, a third transistor T3 of each of the first to third pixel circuits PXC1, PXC2, and PXC3, which is connected (e.g., electrically connected) to the initialization power line IPL, may be disposed at the left side of the storage capacitor of the corresponding pixel circuit.

As described above, with respect to each of the first to third storage capacitors Cst1, Cst2, and Cst3, first and second transistors T1 and T2 may be disposed at the right side thereof, and a third transistor T3 may be disposed at the left side thereof. Direct influence of electrical connection between a first gate electrode GE1 of the first transistor T1 and a second source electrode SE2 of the second transistor T2 on each of the first to third storage capacitors Cst1, Cst2, and Cst3 may be reduced or prevented. Accordingly, the area (or size) of a first gate electrode GE1 of a first transistor T1 in each of the first to third pixel circuits PXC1, PXC2, and PXC3 (or the first to third sub-pixels SPX1, SPX2, and SPX3) may be decreased, and the area of a storage capacitor of the corresponding sub-pixel may be further ensured by the decreased area (or size) of the first gate electrode GE1, thereby increasing the capacitance of the storage capacitor.

In accordance with the disclosure, a first vertical power line may be disposed between a storage capacitor of each sub-pixel and a data line, thereby decreasing the area of a gate electrode of a first transistor (or driving transistor) of each sub-pixel. Thus, the area of the storage capacitor may be ensured.

In accordance with the disclosure, the capacitance of a storage capacitor of each sub-pixel may be increased, thereby improving the reliability of the display device.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
first, second, and third sub-pixels adjacent to each other, each of the first, second, and third sub-pixels including a storage capacitor;
a scan line selectively transferring a scan signal and a control signal to each of the first to third sub-pixels, the scan line extending in a first direction;
a data line transferring a data signal to each of the first to third sub-pixels, the data line extending in a second direction intersecting the first direction; and
a first power line electrically connected to each of the first, second, and third sub-pixels, and the first power line being supplied with a first driving power voltage,
wherein the first power line is disposed between the storage capacitor and the data line.

2. The display device of claim 1, further comprising:
a substrate;
a first insulating layer, a second insulating layer, a third insulating layer, and a fourth insulating layer, sequentially disposed on the substrate;
a second power line supplied with a second driving power voltage, which is different from the first driving power voltage; and
an initialization power line supplied with an initialization power voltage, wherein the first power line includes:
a first vertical power line formed as a first conductive layer disposed on the substrate, and
a first horizontal power line formed as a second conductive layer disposed on the second insulating layer, and
in a plan view, the first vertical power line is disposed between the storage capacitor of each of the first, second, and third sub-pixels and the data line.

3. The display device of claim 2, wherein each of the first, second, and third sub-pixels includes:
a light emitting element;
a first transistor controlling a current of the light emitting element;
a second transistor connected between the data line and a gate electrode of the first transistor, the second transistor being turned on by the scan signal;
a third transistor connected between the initialization power line and a source electrode of the first transistor, the third transistor being turned on by the control signal; and
the storage capacitor including:
a lower electrode electrically connected to the gate electrode of the first transistor and a source electrode of the second transistor, and
an upper electrode electrically connected to the source electrode of the first transistor and a source electrode of the third transistor.

4. The display device of claim 3, wherein the first, second, and third transistors are disposed at a side of the storage capacitor.

5. The display device of claim 3, wherein
the second power line includes:
a second vertical power line formed as the first conductive layer, and
a second horizontal power line formed as the second conductive layer, and
in a plan view, the storage capacitor is disposed between the second vertical power line and the first vertical power line.

6. The display device of claim 5, wherein, in a plan view, the initialization power line is disposed between the first vertical power line and the data line.

7. The display device of claim 6, wherein the gate electrode of the first transistor of each of the first, second, and third sub-pixels is disposed between the storage capacitor and the first vertical power line.

8. The display device of claim 3, wherein
the lower electrode is disposed on the substrate, and
the upper electrode is disposed on the first insulating layer to overlap the lower electrode with the first insulating layer interposed between the lower electrode and the upper electrode.

9. The display device of claim 8, wherein the upper electrode and an active pattern layer of each of the first, second, and third transistors are disposed on a same layer.

10. The display device of claim 9, wherein the upper electrode is integral with the source electrode of the first transistor and the source electrode of the third transistor.

11. The display device of claim 3, wherein the light emitting element includes:
a first electrode formed as a third conductive layer disposed on the fourth insulating layer;
a light emitting layer disposed on the first electrode; and
a second electrode disposed on the light emitting layer.

12. The display device of claim 11, wherein the first electrode is electrically connected to the source electrode of the first transistor through a contact part passing through the second to fourth insulating layers.

13. The display device of claim 5, wherein, in a plan view, the initialization power line is disposed between the second vertical power line and the storage capacitor.

14. The display device of claim 13, wherein
in a plan view, the initialization power line is disposed at a first side of the storage capacitor, and
in a plan view, the first vertical power line is disposed at a second side of the storage capacitor.

15. The display device of claim 14, wherein
in a plan view, the third transistor among the first, second, and third transistors is disposed at the first side of the storage capacitor, and
in a plan view, the first and second transistors among the first, second, and third transistors are disposed at the second side of the storage capacitor.

16. The display device of claim 3, wherein each of the first, second, and third sub-pixels further includes:
an encapsulation layer disposed over the light emitting element;
a color filter layer disposed on the encapsulation layer; and
an overcoat layer disposed over the color filter layer.

17. A display device comprising:
a substrate;
first, second, third, and fourth insulating layers sequentially stacked on the substrate;
first, second, and third sub-pixels each including:
a pixel circuit including a storage capacitor and first, second, and third transistors, which are disposed on the substrate, and
a light emitting element electrically connected to the pixel circuit;
a scan line disposed on the substrate, the scan line selectively transferring a scan signal and a control signal to each of the first, second, and third sub-pixels;
a data line transferring a data signal to each of the first, second, and third sub-pixels;
a first power line supplied with a first power voltage;
a second power line supplied with a second power voltage, which is different from the first power voltage; and
an initialization power line supplied with an initialization power voltage, which is different from the first and second power voltages,
wherein a gate electrode of the first transistor is disposed between the storage capacitor and the first power line.

18. The display device of claim 17, wherein
the first power line includes:
a first vertical power line disposed on the substrate, and
a first horizontal power line disposed on the second insulating layer, and
the first vertical power line is disposed between the storage capacitor and the data line.

19. The display device of claim 18, wherein, in a plan view, the first, second, and third transistors are disposed at a side of the storage capacitor.

20. The display device of claim 18, wherein, in a plan view, the storage capacitor is disposed between the initialization power line and the first vertical power line.
